(19) United States
(12) Patent Application Publication
(10) Pub. No.: US 2026/0173617 A1
(43) Pub. Date: Jun. 18, 2026

(54) DISPLAY PANEL AND ELECTRONIC APPARATUS INCLUDING THE DISPLAY PANEL

(71) Applicant: Samsung Display Co., LTD., Yongin-si (KR)

(72) Inventors: Jinwoo CHOI, Yongin-si (KR); Seongwon KIM, Yongin-si (KR); Jangyeol YOON, Yongin-si (KR); Jongho HONG, Yongin-si (KR)

(21) Appl. No.: 19/424,586

(22) Filed: Dec. 18, 2025

(30) Foreign Application Priority Data
Dec. 18, 2024 (KR) 10-2024-0190444

(51) Int. Cl. H10H 29/49; H10K 59/131

(52) U.S. Cl. CPC H10H 29/49; H10K 59/131

(57) ABSTRACT

A display panel includes a first island portion and a second island portion adjacent to each other in a first direction, and a bridge portion connecting the first and second island portions. Each of the first and second island portions includes at least one side crossing a first imaginary line passing through centers of the first and second island portions and extending in the first direction. The bridge portion includes a first curved portion, a second curved portion, and a straight portion between the first and second curved portions. The straight portion is between a first side of the first island portion and a second side of the second island portion facing each other, the first curved portion is connected to a third side crossing the first side, and the second curved portion is connected to a fourth side crossing the second side.

This application claims priority to Korean Patent Application No. 10-2024-0190444, filed on Dec. 18, 2024, and all the benefits accruing therefrom under 35 U.S.C. § 119, the content of which in its entirety is herein incorporated by reference.

### BACKGROUND

### Field

Embodiments of the present invention relate to a display panel, for example, a flexible display panel, and an electronic apparatus including the display panel.

### Description of the Related Art

As display panels that visually display electrical signals are developed, various display panels having excellent characteristics such as, for example, being slim, being lightweight, low power consumption, and the like have been introduced. As an example, flexible display panels that are foldable or rollable in a roll shape have been introduced. Recently, research and development into display panels of various structures, such as stretchable display panels that may change into various shapes are actively in progress.

### SUMMARY

Embodiments of the present invention may provide a display panel, for example, a flexible display panel, and an electronic apparatus including the display panel.

### Technical Solution

According to an embodiment of the present invention, a display panel including a display area and a non-display area around the display area includes: island portions apart from each other in a first direction and a second direction crossing the first direction in the display area, wherein light-emitting elements are arranged in each of the island portions; and bridge portions each connecting two adjacent island portions among the island portions, wherein the island portions include a first island portion and a second island portion adjacent to each other in the first direction, each of the first island portion and the second island portion includes at least one side crossing a first imaginary line passing through a center of the first island portion and a center of the second island portion, and the first imaginary line extends in the first direction, wherein a bridge portion which is among the bridge portions and connects the first island portion and the second island portion to each other includes: a first curved portion connected to the first island portion; a second curved portion connected to the second island portion; and a straight portion between the first curved portion and the second curved portion, and wherein the straight portion is located between a first side of the first island portion and a second side of the second island portion facing each other, the first curved portion is connected to a third side of the first island portion crossing the first side of the first island portion, and the second curved portion is connected to a fourth side of the second island portion crossing the second side of the second island portion.

The first curved portion and the second curved portion may have a point-symmetrical relationship with respect to a center of the straight portion.

The first curved portion may be connected to the third side of the first island portion and disposed adjacent to a corner between the first side and the third side of the first island portion, and the second curved portion may be connected to the fourth side of the second island portion and disposed adjacent to a corner between the second side and the fourth side of the second island portion.

The corner between the first side and the third side of the first island portion may include a chamfered portion.

Each of the first curved portion and the second curved portion may have a shape of an arc having a central angle, and the central angle may be greater than 180° and less than 360°.

A width of the first curved portion may be substantially equal to a width of the straight portion.

A width of a portion of the first curved portion may be greater than a width of the straight portion.

The straight portion may include a side facing the first side of the first island portion, and the side of the straight portion may be substantially parallel to the first side of the first island portion.

The straight portion may include a side facing the first side of the first island portion, and the side of the straight portion may extend in a direction oblique with respect to the first side of the first island portion.

A length of the straight portion may be less than a length of the first side of the first island portion.

The island portions may further include a third island portion and a fourth island portion arranged in the second direction and disposed adjacent to the first island portion and the second island portion, wherein the center of the first island portion, the center of the second island portion, a center of the third island portion, and a center of the fourth island portion may be respectively disposed on vertexes of an imaginary quadrilateral.

The straight portion of the bridge portion may cross one side of the imaginary quadrilateral.

The imaginary quadrilateral may include a square or a rhombus.

The display panel is stretchable, and when the display panel is stretched, the first island portion may rotate clockwise or counterclockwise around an axis passing through the center of the first island portion.

The first island portion may include pixel driving circuits and light-emitting elements electrically connected to the pixel driving circuits, and an arrangement direction of the pixel driving circuits and an arrangement direction of the light-emitting elements may be different from each other.

According to an embodiment of the present invention, a display panel including a display area and a non-display area around the display area includes: island portions apart from each other in a first direction and a second direction crossing the first direction in the display area; and bridge portions each connecting two adjacent island portions among the island portions, wherein the island portions includes a first island portion and a second island portion adjacent to each other in the first direction, each of the first island portion and the second island portion includes at least one side crossing a first imaginary line passing through a center of the first island portion and a center of the second island portion, and the first imaginary line extends in the first direction, wherein the first island portion includes pixel driving circuits and light-emitting elements electrically connected to the pixel driving circuits, and wherein an arrangement direction of the pixel driving circuits and an arrangement direction of the light-emitting elements are different from each other.

The arrangement direction of the light-emitting elements may be the first direction.

A bridge portion which is among the bridge portions and connects the first island portion and the second island portion to each other may include: a first curved portion connected to the first island portion; a second curved portion connected to the second island portion; and a straight portion between the first curved portion and the second curved portion, wherein the straight portion may be located between a first side of the first island portion and a second side of the second island portion facing each other, the first curved portion may be connected to a third side of the first island portion crossing the first side of the first island portion, and the second curved portion may be connected to a fourth side of the second island portion crossing the second side of the second island portion.

The first curved portion and the second curved portion may have a point-symmetrical relationship with respect to a center of the straight portion.

The first curved portion may be connected to the third side of the first island portion and disposed adjacent to a corner between the first side and the third side of the first island portion, and the second curved portion may be connected to the fourth side of the second island portion and disposed adjacent to a corner between the second side and the fourth side of the second island portion.

The corner between the first side and the third side of the first island portion may include a chamfered portion.

A width of a portion of the first curved portion may be greater than a width of the straight portion.

A width of the first curved portion may be substantially equal to a width of the straight portion.

Each of the first curved portion and the second curved portion may have a shape of an arc having a central angle, and the central angle may be greater than 180° and less than 360°.

The straight portion may include a side facing the first side of the first island portion, and the side of the straight portion may be substantially parallel to the first side of the first island portion.

The straight portion may include a side facing the first side of the first island portion, and the side of the straight portion may extend in a direction oblique with respect to the first side of the first island portion.

A length of the straight portion may be less than a length of the first side of the first island portion.

The island portions may further include a third island portion and a fourth island portion arranged in the second direction and disposed adjacent to the first island portion and the second island portion, wherein the center of the first island portion, the center of the second island portion, a center of the third island portion, and a center of the fourth island portion may be respectively disposed on vertexes of imaginary quadrilateral.

The imaginary quadrilateral may include a square or a rhombus.

The display panel is stretchable, and when the display panel is stretched, the first island portion may rotate clockwise or counterclockwise around an axis passing through the center of the first island portion.

An embodiment of the present invention provides an electronic apparatus including the display panel according to the embodiments and a housing in which the display panel is accommodated.

The electronic apparatus may further include a strain sensor measuring a physical quantity according to stretching of the display panel.

### Effects of Disclosure

According to an embodiment of the present invention, a display panel which is stretchable in various directions, and an electronic apparatus including the display panel may be provided. The display panel may efficiently utilize a space by reducing an area occupied in a display area by a bridge portion. This effect is an example, and the scope of the present invention is not limited by this effect.

### BRIEF DESCRIPTION OF THE DRAWINGS

FIG. 1 is a schematic perspective view of a display panel according to an embodiment of the present invention.

FIGS. 2A and 2B are perspective views of the display panel of FIG. 1 in a state stretched in a first direction.

FIG. 2C is a perspective view of the display panel of FIG. 1 in a state stretched in a second direction.

FIG. 2D is a perspective view of the display panel of FIG. 1 in a state stretched in the first direction and the second direction.

FIG. 2E is a perspective view of the display panel of FIG. 1 in a state stretched in a third direction.

FIG. 3 is a schematic plan view of a display panel according to an embodiment of the present invention.

FIG. 4A is an enlarged plan view of a portion of a display panel, illustrating a region IV of FIG. 3 according to an embodiment of the present invention.

FIG. 4B is an enlarged plan view of a portion of a display panel, illustrating a region IV of FIG. 3 according to an embodiment of the present invention.

FIG. 4C is an enlarged plan view of a portion of a display panel, illustrating a region IV of FIG. 3 according to an embodiment of the present invention.

FIG. 5A is a schematic cross-sectional view of an island portion and a bridge portion disposed in a display area of a display panel according to an embodiment of the present invention.

FIG. 5B is a schematic plan view of the arrangement of a light-emitting element and a pixel driving circuit of an island portion disposed in a display area of a display panel according to an embodiment of the present invention.

FIGS. 6A to 6C are equivalent circuit diagrams of a light-emitting element and a pixel driving circuit electrically connected thereto of a display panel according to an embodiment of the present invention.

FIGS. 7A and 7B are schematic cross-sectional views of a light-emitting element of a display panel according to an embodiment of the present invention.

FIG. 8 is an excerpted plan view of island portions and bridge portions disposed in a display area of a display panel according to an embodiment of the present invention.

FIG. 9 is a plan view of two adjacent island portions and a bridge portion therebetween of a display panel according to an embodiment of the present invention.

FIG. 10 is a plan view of two adjacent island portions and a bridge portion therebetween of a display panel according to an embodiment of the present invention.

FIG. 11 is a plan view of two adjacent island portions and a bridge portion therebetween of a display panel according to an embodiment of the present invention.

FIG. 12 illustrates a structure of a corner of an island portion and a bridge therearound of a display panel according to an embodiment of the present invention.

FIG. 13 is a plan view of a display panel stretched according to an embodiment of the present invention.

FIG. 14A is a schematic perspective view of an electronic apparatus including a display panel according to an embodiment of the present invention.

FIG. 14B is a schematic block diagram of an electronic apparatus including a display panel according to an embodiment of the present invention.

FIGS. 15A to 15I are schematic perspective views of an electronic apparatus including a display panel according to an embodiment of the present invention.

### DETAILED DESCRIPTION

As the present invention allows for various changes and numerous embodiments, certain embodiments will be illustrated in the drawings and described in the detailed description. Effects and features of the present invention, and methods for achieving them will be clarified with reference to embodiments described herein with reference to the drawings. However, the present invention is not limited to embodiments described herein and may be implemented in various forms.

Hereinafter, embodiments of the present invention will be described with reference to the accompanying drawings, wherein, like or corresponding elements are given like reference characters when describing with reference to the drawings, and a repeated description thereof is omitted.

In embodiments below, such terms as first and second are not used in a limited meaning and are used for the purpose of distinguishing one element from another element.

In embodiments below, the singular expressions include the plural expressions unless the context clearly indicates otherwise.

In embodiments below, the terms such as, for example, comprise or have specify the presence of stated features or elements described in the specification but do not preclude possibility of the addition of one or more other features or elements.

In embodiments below, when a layer, region, or element is referred to as being on another portion, it may include not only a case where the layer, region, or element is directly on the other portion, but also a case where intervening layers, regions, or elements are disposed therebetween.

Sizes of elements in the drawings may be exaggerated or reduced for convenience of explanation. As an example, the size and thickness of each element illustrated in the drawings are arbitrarily represented for convenience of description, and thus, the present invention is not necessarily limited thereto.

In the case where a certain embodiment may be implemented differently, a specific process order may be performed in the order different from the described order. As an example, two processes successively described may be simultaneously performed substantially and performed in the opposite order of the described order.

In the present specification, “A and/or B” means A or B, or A and B. In some aspects, “at least one of A and B” means A or B, or A and B.

In embodiments below, when a layer, region, or element is referred to as being connected, it includes not only a case where the layer, region, or element is directly connected, but also a case where the layer, region, or element is indirectly connected with another layer, region, or element disposed therebetween. For example, in the present specification, when a layer, region, or element is referred to as being electrically connected, it represents a case where the layer, region, or element is directly electrically connected and/or a case where the layer, region, or element may be indirectly electrically connected with another layer, region, or element disposed therebetween.

The x-axis, the y-axis and the z-axis are not limited to three axes of the rectangular coordinate system, and may be interpreted in a broader sense including same. For example, x axis, y axis, and z axis may be perpendicular to one another, or may represent different directions that are not perpendicular to one another.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

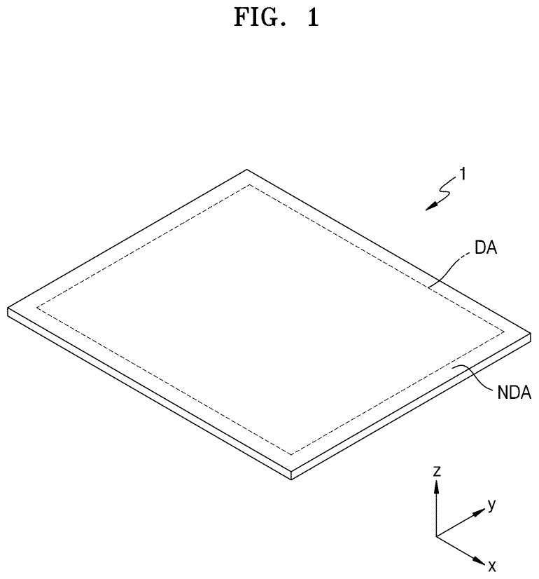

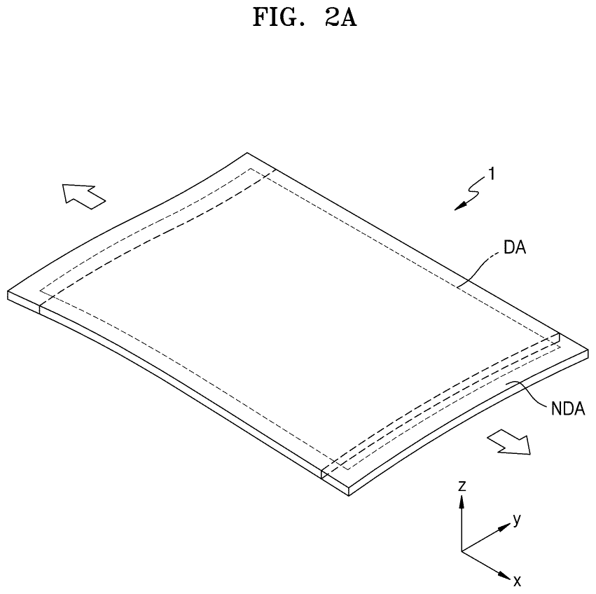

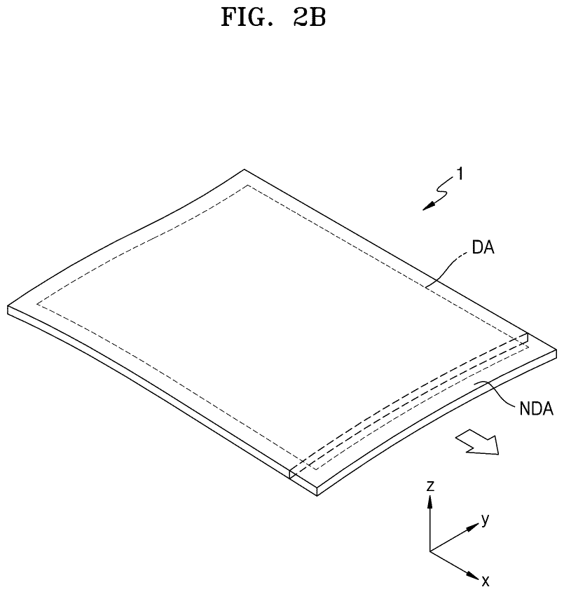

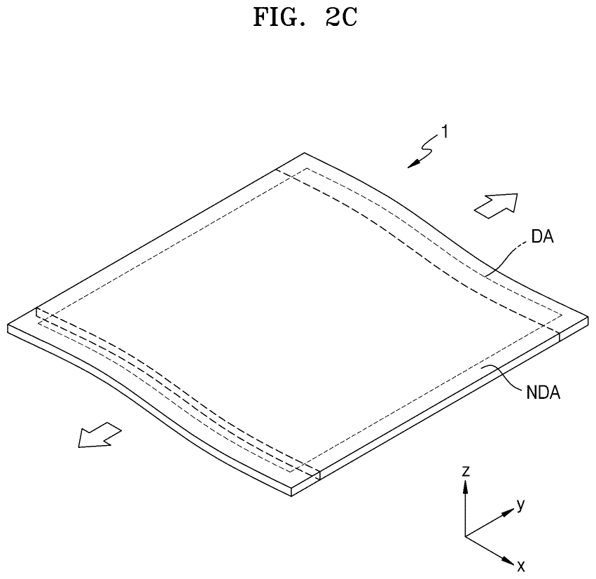

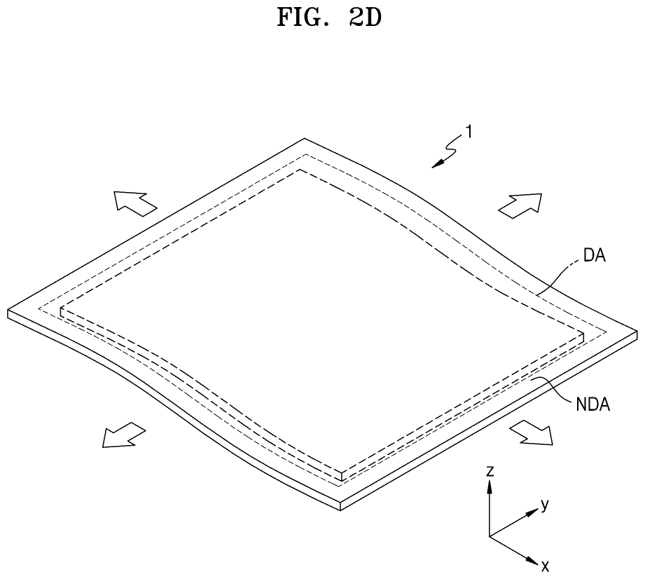

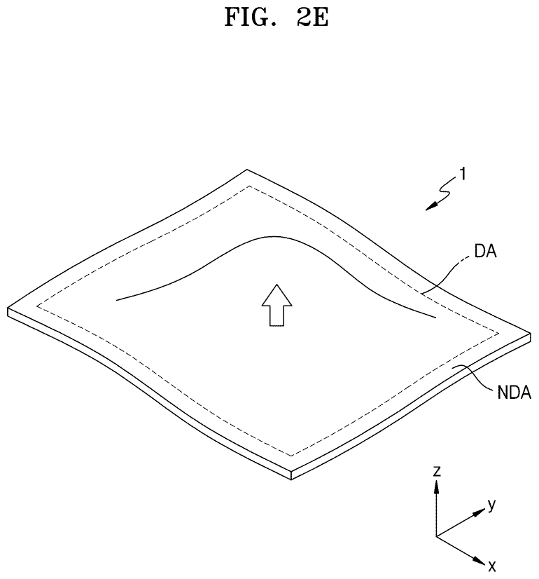

FIG. 1 is a schematic perspective view of a display panel 1 according to an embodiment of the present invention. FIGS. 2A and 2B are perspective views of the display panel 1 of FIG. 1 in a state stretched in a first direction. FIG. 2C is a perspective view of the display panel 1 of FIG. 1 in a state stretched in a second direction. FIG. 2D is a perspective view of the display panel of FIG. 1 in a state stretched in the first direction and the second direction. FIG. 2E is a perspective view of the display panel 1 of FIG. 1 in a state stretched in a third direction.

Referring to FIG. 1, the display panel 1 may include a display area DA and a non-display area NDA. The display area DA may include a plurality of pixels. The display panel 1 may be configured to display images by using light emitted from the plurality of pixels. The non-display area NDA may be disposed outside the display area DA. The non-display area NDA is a region in which the pixels are not disposed and may surround the display area DA entirely.

The display panel 1 may stretch or shrink in various directions. The display panel 1 may be stretched in the first direction (e.g., x direction and/or −x direction) by external force exerted by an external object or a user. In an embodiment, as illustrated in FIGS. 2A and 2B, the display area DA and/or the non-display area NDA of the display panel 1 may be stretched in the first direction (e.g., x direction and/or −x direction). As an example, as illustrated in FIG. 2A, the display area DA and/or the non-display area NDA may be stretched in the x direction and-x direction, or as illustrated in FIG. 2B, be stretched in the x direction with one side of the display panel 1 fixed.

The display panel 1 may be stretched in the second direction (e.g., y direction and/or −y direction) by external force exerted by an external object or a user. In an embodiment, as illustrated in FIG. 2C, the display area DA and/or the non-display area NDA of the display panel 1 may be stretched in the y direction and-y direction. In another embodiment, the display panel 1 may be stretched in the y direction or −y direction with one side of the display panel 10 fixed.

The display panel 1 may be stretched in a plurality of directions, for example, the first direction (e.g., x direction and/or −x direction) and the second direction (e.g., y direction and/or −y direction) by external force exerted by an external object or a portion of a person's body. As illustrated in FIG. 2D, the display area DA and/or the non-display area NDA of the display panel 1 may be stretched in a ±x direction and a ±y direction.

The display panel 1 may be stretched in a third direction (e.g., z direction and/or −z direction) by external force exerted by an external object or a portion of a person's body. In an embodiment, FIG. 2E illustrates a portion of the display panel 1, for example, a partial region of the display area DA protrudes in the z direction. In another embodiment, a portion of the display panel 1, for example, a partial region of the display area DA may protrude in the −z direction (or be recessed in the z direction).

Although it is illustrated in FIGS. 2A to 2E that the display panel 1 is stretched in the first direction, the second direction, and/or the third direction, embodiments of the present disclosure are not limited thereto. In another embodiment, the display panel 1 may be variously transformed into an irregular shape, such as, for example, being bent or twisted with two or more axes.

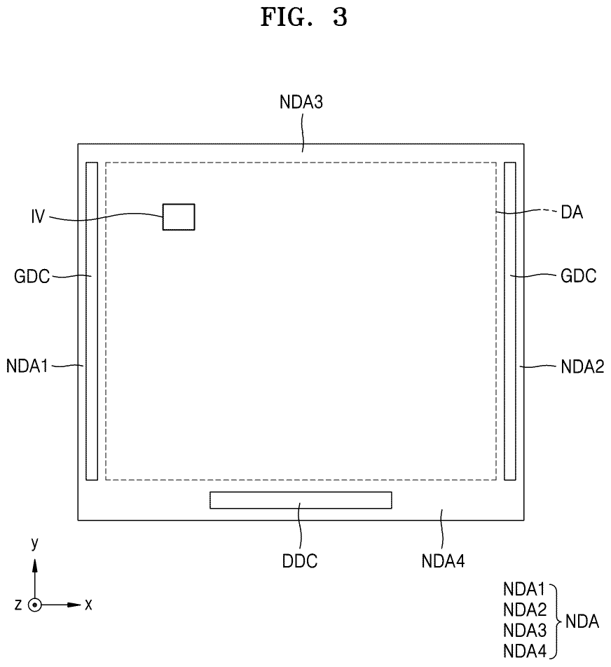

FIG. 3 is a schematic plan view of the display panel 1 according to an embodiment of the present invention.

The plurality of pixels may be arranged in the display area DA of the display panel 1. Each pixel may include sub-pixels emitting light of different colors. A light-emitting element corresponding to each sub-pixel may be disposed in the display area DA. A circuit may be located in the non-display area NDA around the display area DA, wherein the circuit provides electrical signals to light-emitting elements disposed in the display area DA and transistors electrically connected to the light-emitting elements. A gate driving circuit GDC may be disposed in each of a first non-display area NDA1 and a second non-display area NDA2 disposed on two opposite sides with the display area DA therebetween. The gate driving circuit GDC may include drivers for providing electrical signals to a gate electrode of each of transistors electrically connected to light-emitting elements. Although it is illustrated in FIG. 3 that the gate driving circuit GDC is disposed in each of the first non-display area NDA1 and the second non-display area NDA2, embodiments of the present disclosure are not limited thereto. In another embodiment, the gate driving circuit GDC may be disposed in one of the first non-display area NDA1 and the second non-display area NDA2.

A data driving circuit DDC may be disposed in a third non-display area NDA3 and/or a fourth non-display area NDA4 connecting the first non-display area NDA1 and the second non-display area NDA2 to each other. In an embodiment, it is illustrated in FIG. 3 that the data driving circuit DDC is disposed in the fourth non-display area NDA4. In another embodiment, the data driving circuit DDC may be disposed in each of the third non-display area NDA3 and fourth non-display area NDA4.

Although it is illustrated in FIG. 3 that the data driving circuit DDC is disposed in the fourth non-display area NDA4 of the display panel 1, embodiments of the present disclosure are not limited thereto. In another embodiment, the display panel 1 may further include a flexible circuit board (not illustrated) electrically connected through a terminal section (not illustrated) disposed in the fourth non-display area NDA4, and the data driving circuit DDC may be disposed on the flexible circuit board.

In another embodiment, an elongation of the non-display area NDA may be equal to or less than an elongation of the display area DA. In an embodiment, an elongation of the non-display area NDA may be different for each region. As an example, the first non-display area NDA1, the second non-display area NDA2, and the third non-display area NDA3 may have substantially the same elongation, but an elongation of the fourth non-display area NDA4 may be less than an elongation of each of the first non-display area NDA1, the second non-display area NDA2, and the third non-display area NDA3. In the present specification, an elongation is a numerical value representing a change ΔL/L in length by which the display panel 1 may be stretched without a physical damage to the display panel 1 when external force is applied to the display panel 1. Here, ΔL is an amount of change in length of the display panel 1, and L represents an initial length of the display panel 1.

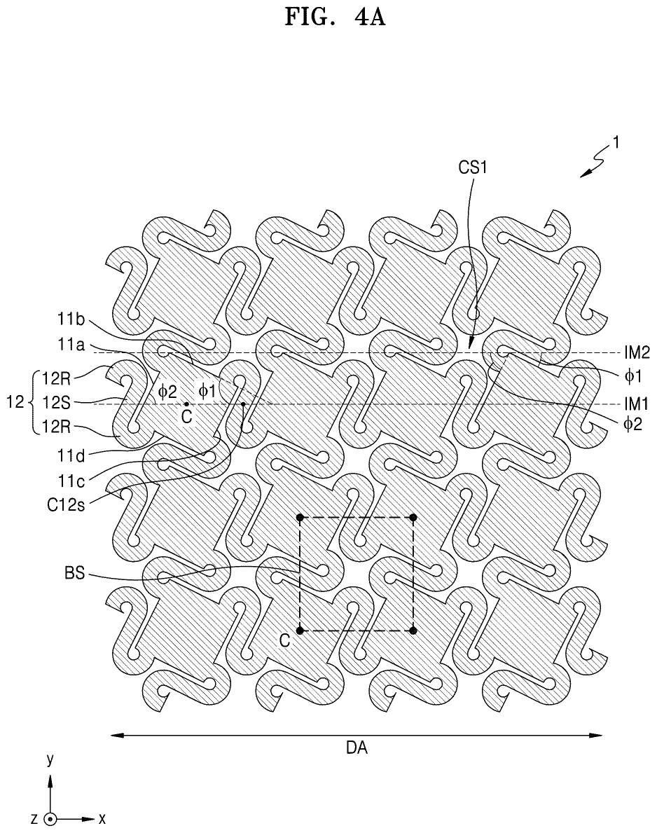

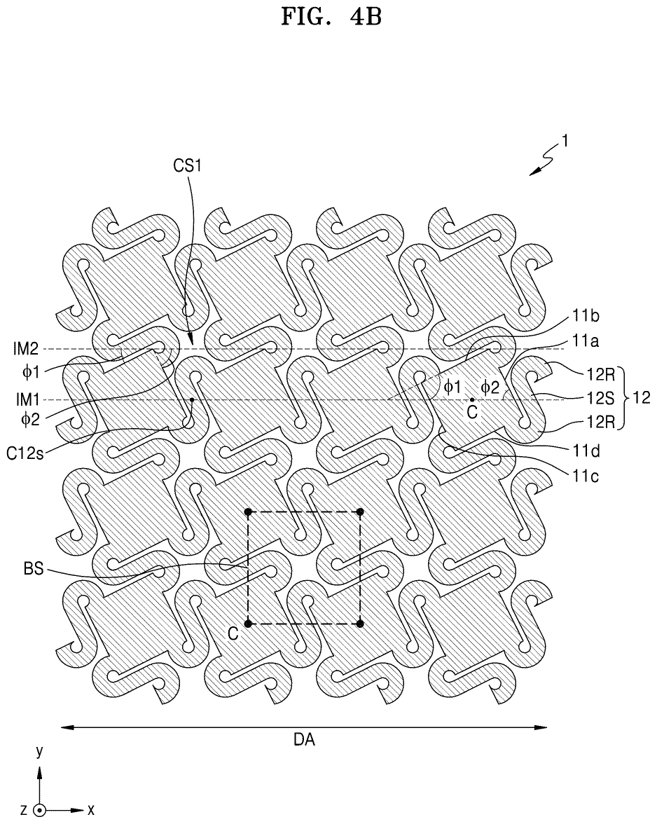

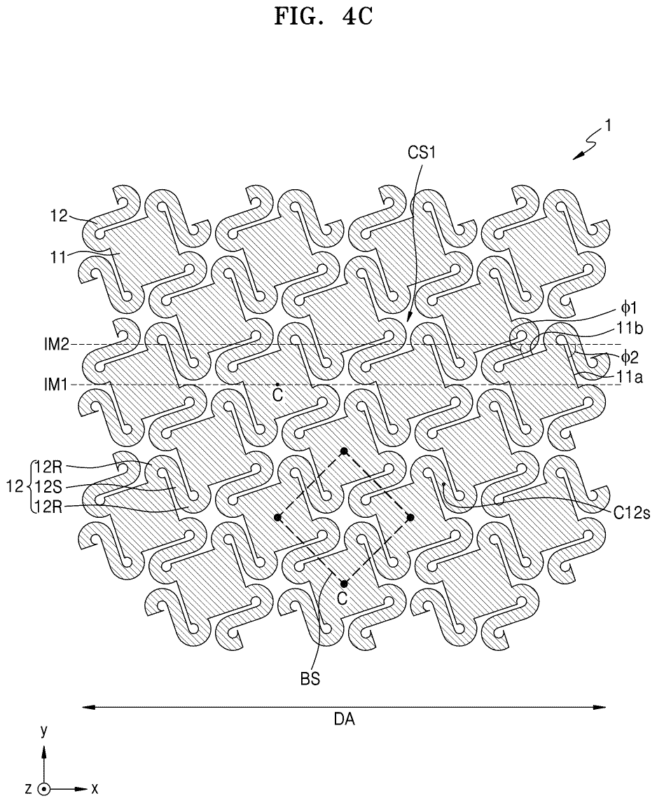

FIGS. 4A to 4C are enlarged plan views of a portion of the display panel 1, illustrating a region IV of FIG. 3 according to an embodiment of the present invention.

Referring to FIGS. 4A to 4C, the display panel 1 may include two island portions 11 and bridge portions 12 connecting two adjacent island portions 11, wherein the two island portions 11 are apart from each other in the first direction (e.g., x direction or −x direction) and the second direction (e.g., y direction or −y direction) in the display area DA. The bridge portions 12 may be apart from each other by a first opening CS1 located between the bridge portions 12.

The island portions 11 may be arranged in the first direction (e.g., x direction or −x direction) and the second direction (e.g., y direction or −y direction) crossing the first direction (e.g., x direction or −x direction). It is illustrated that centers of adjacent four island portions 11 are located on vertexes of an imaginary quadrilateral BS with the first opening CS1 centered. The imaginary quadrilateral BS may have a shape such as, for example, a square, a rhombus, or a parallelogram. In an embodiment, FIGS. 4A and 4B show that the imaginary quadrilateral BS is a square, and FIG. 4C illustrates that the imaginary quadrilateral BS is a rhombus.

In an embodiment, at least one of sides of each island portion 11 may be oblique with respect to a first imaginary line IM1 connecting centers C of the island portions 11 in the first direction (e.g., x direction or −x direction) and/or the second direction (e.g., y direction or −y direction), and may cross the first imaginary line IM1. In this regard, it is illustrated in FIGS. 4A to 4C that each island 11 includes first to fourth sides 11a, 11b, 11c, and 11d, and each of the first to fourth sides 11a, 11b, 11c, and 11d extends in a direction oblique with respect to the first imaginary line IM1 connecting the centers C of the island portions 11. At least one of the first to fourth sides 11a, 11b, 11c, and 11d, for example, the first side 11a and the third side 11c may cross the first imaginary line IM1. Hereinafter, for convenience of description, although each of the island portions 11 is a quadrilateral and includes four sides, embodiments of the present disclosure are not limited thereto. In another embodiment, the island portion 11 may have a polygonal such as, for example, pentagons and hexagons, or a circular shape or an elliptical shape. Hereinafter, to distinguish one side of the island portion 11 from another side, the sides are referred to as the first to fourth sides 11a, 11b, 11c, and 11c.

In an embodiment, an angle between each side of the island portion 11 and the first imaginary line IM1 may be greater than 0° and less than 90°. An angle between a second imaginary line IM2 parallel to the first imaginary line IM1 and passing through one of corners of each island portion 11, and each side of the island portion 11 may be greater than 0° and less than 90°.

As an example, a first angle φ1 between the second side 11b and the second imaginary line IM2 may be also greater than 0° and less than 90°. As an example, the first angle φ1 may be greater than 0° and equal to or less than 45°. The first angle φ1 between the second side 11b and the second imaginary line IM2 may be equal to an angle (first angle φ1) between the second side 11b and the first imaginary line IM1.

A second angle φ2 between the first side 11a and the first imaginary line IM1 may be greater than 0° and less than 90°. As an example, referring to FIGS. 4A to 4C, the second angle φ2 may be equal to or greater than 45° and less than 90°. The second angle φ2 between the first side 11a and the first imaginary line IM1 may be equal to an angle (second angle φ2) between the first side 11a and the second imaginary line IM2.

Similarly, an angle between the third side 11c and the first imaginary line IM1 or an angle between the third side 11c and the second imaginary line IM2 may be equal to the second angle φ2. An angle between the fourth side 11d and the first imaginary line IM1 or an angle between the fourth side 11d and the second imaginary line IM2 may be equal to the first angle φ1.

Although it is illustrated in FIGS. 4A to 4C that the first angle φ1 is less than the second angle φ2, embodiments of the present disclosure are not limited thereto. In another embodiment, the first angle φ1 may be greater than the second angle φ2.

Each island portion 11 may be connected to a plurality of bridge portions 12. The plurality of bridge portions 12 connected to one of the island portions 11 may respectively correspond to a plurality of sides of the corresponding island portion 11. In an embodiment, each island portion 11 may be connected to four bridge portions 12, and the four bridge portions 12 may be respectively connected (e.g., directly connected) to four sides of the island portion 11. Two bridge portions 12 located on opposite sides with the island portion 11 therebetween in the first direction (e.g., x direction or −x direction) may be respectively connected to two sides (e.g., first side 11a and third side 11c) of the island portion 11 which are opposite sides with the center C therebetween. The remaining two bridge portions 12 located on opposite sides with the island portion 11 therebetween in the second direction (e.g., y direction or −y direction) may be respectively connected to other two sides (e.g., second side 11b and fourth side 11d) of the island portion 11 which are opposite sides with the center C therebetween.

The bridge portion 12 may have a serpentine shape. The bridge portion 12 may include two curved portions 12R and a straight portion 12S between the two curved portions 12R.

The straight portion 12S of the bridge portion 12 may be located between one sides of two adjacent island portions 11. As an example, the first side 11a of one island portion 11 of two adjacent island portions 11, and the third side 11c of the other island portion 11 may be apart from each other with a gap, and the straight portion 12S may be located therebetween.

As illustrated in FIGS. 4A and 4C, one curved portion 12R of two curved portions 12R of the bridge portion 12 may connect the straight portion 12S to a side of one island portion 11, and may be curved counterclockwise from one end of the straight portion 12S toward the side of the one island portion 11. The other curved portion 12R of the two curved portions 12R of the bridge portion 12 may connect the straight portion 12S to a side of another island portion 11, and may be curved counterclockwise from the other end of the straight portion 12S toward the side of the other island portion 11. Two curved portions 12R of the bridge portion 12 may have a point-symmetrical relationship with respect to a center C12s of the straight portion 12S.

As illustrated in FIG. 4B, one curved portion 12R of two curved portions 12R of the bridge portion 12 may connect the straight portion 12S to a side of one island portion 11, and may be curved clockwise from one end of the straight portion 12S toward the side of the one island portion 11. The other curved portion 12R of the two curved portions 12R of the bridge portion 12 may connect the straight portion 12S to a side of another island portion 11, and may be curved clockwise from the other end of the straight portion 12S toward the side of the other island portion 11. Two curved portions 12R of the bridge portion 12 may have a point-symmetrical relationship with respect to a center C12s of the straight portion 12S.

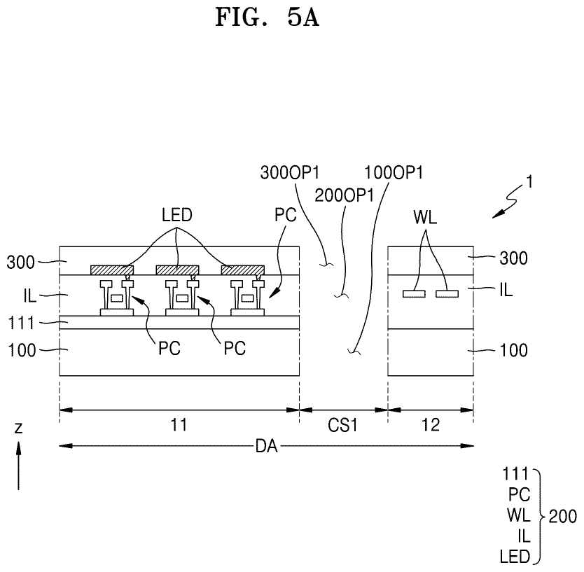

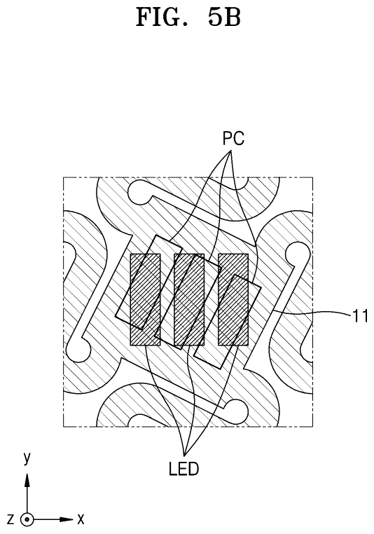

FIG. 5A is a schematic cross-sectional view of the island portion 11 and the bridge portion 12 disposed in the display area DA of the display panel 1 according to an embodiment of the present invention, and FIG. 5B is a schematic plan view of the arrangement of a light-emitting element LED and a pixel driving circuit PC of the island portion 11 disposed in the display area DA of the display panel 1 according to an embodiment of the present invention.

Referring to FIG. 5A, the island portion 11 and the bridge portion 12 disposed in the display area DA may be apart from each other with the first opening CS1 therebetween. The island portion 11 is a region in which pixels are arranged and may include light-emitting elements LED respectively corresponding to the pixels, and a circuit (referred to as a pixel driving circuit PC, hereinafter) for driving each light-emitting element LED. The bridge portion 12 may include a wiring WL electrically connected to pixel driving circuits PC respectively disposed in adjacent island portions 11.

Referring to FIGS. 5A and 5B, when examining the island portion 11, a buffer layer 111 including an inorganic insulating material may be disposed on a substrate 100, and the pixel driving circuit PC may be disposed on the buffer layer 111. An insulating layer IL including an inorganic insulating material and/or an organic insulating material may be disposed between the pixel driving circuit PC and the light-emitting element LED. The light-emitting element LED may be disposed on the insulating layer IL and electrically connected to the pixel driving circuit PC corresponding thereto. The light-emitting elements LED may emit light of different colors or light of the same color. In an embodiment, the light-emitting elements LED may be configured to emit red, green, or blue light. In an embodiment, the light-emitting elements LED may be configured to emit white light. In another embodiment, the light-emitting elements LED may be configured to emit red, green, blue light, or white light.

In a plan view, an arrangement direction of the pixel driving circuits PC and an arrangement direction of the light-emitting elements LED may be different from each other. An arrangement direction of the pixel driving circuits PC may cross an arrangement direction of the light-emitting elements LED. In an embodiment, as illustrated in FIG. 5B, the light-emitting elements LED may be arranged apart from each other in the arrangement direction of the island portion 11, for example, the first direction (e.g., x direction or −x direction) as described herein with reference to FIG. 4A and the like. The pixel driving circuits PC may be arranged in a direction from one side of the island portion 11 toward another side facing the one side.

The substrate 100 may include polymer resin such as, for example, polyethersulfone, polyarylate, polyetherimide, polyethylene naphthalate, polyethylene terephthalate, polyphenylene sulfide, polyimide, polycarbonate, cellulose tri acetate, cellulose acetate propionate, and the like. In an embodiment, the substrate 100 may be a single layer including the polymer resin. In another embodiment, the substrate 100 may have a multi-layered structure including a base layer and a barrier layer, wherein the base layer includes the above polymer resin and the barrier layer includes an inorganic insulating material. The substrate 100 including the polymer resin may be flexible, rollable, or bendable.

In an embodiment, although it is illustrated in FIGS. 5A and 5B that three pixel driving circuits PC are disposed in each island portion 11, and three light-emitting elements LED are respectively connected to the pixel driving circuits PC, embodiments of the present disclosure are not limited thereto. In another embodiment, the number of pixel driving circuits PC and the number of light-emitting elements LED disposed in the island portion 11 may be one, two, or four or more.

An encapsulation layer 300 may be disposed on the light-emitting element LED and may protect the light-emitting element LED from external force and/or moisture transmission. The encapsulation layer 300 may include an inorganic encapsulation layer and/or an organic encapsulation layer. In an embodiment, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as, for example, resin. In an embodiment, the encapsulation layer 300 may include urethane epoxy acrylate. The encapsulation layer 300 may include a photosensitive material, for example, a material such as, for example, a photoresist.

When examining the bridge portion 12, the insulating layer IL including an organic insulating material may be disposed on the substrate 100. In an example in which the display panel 1 stretches, the bridge portion 12, which changes its shape relatively significantly, may not have a layer including an inorganic insulating material that is prone to cracking, unlike the island portion 11.

In an embodiment, the substrate 100 corresponding to the bridge portion 12 may have the same stack structure as a stack structure of the substrate 100 corresponding to the island portion 11. In an embodiment, the substrate 100 corresponding to the bridge portion 12 and the substrate 100 corresponding to the island portion 11 may be polymer resin layers simultaneously formed during the same process. In another embodiment, the substrate 100 corresponding to the bridge portion 12 may have a different stack structure from a stack structure of the substrate 100 corresponding to the island portion 11. In an embodiment, the substrate 100 corresponding to the bridge portion 12 may have a multi-layered structure including a base layer that includes a polymer resin and a barrier layer that includes an inorganic insulating material, and the substrate 100 corresponding to the bridge portion 12 may have a structure of a polymer resin layer in which a layer including an inorganic insulating material is absent.

As described herein, the wirings WL of the bridge portion 12 may be signal lines (e.g., a gate line, a data line, and the like) for providing electrical signals, or voltage lines (e.g., a driving voltage line, an initialization voltage line, and the like) for proving voltages to transistors included in the pixel driving circuit PC of the island portion 11. The encapsulation layer 300 may be disposed on also the bridge portion 12. In another embodiment, the encapsulation layer 300 may not be present on the bridge portion 12.

Referring to FIGS. 4A to 4C, and 5A, the substrate 100 corresponding to the island portion 11 and the substrate 100 corresponding to the bridge portion 12 may be connected to each other. In other words, the plan views illustrated in FIGS. 4A to 4C may be substantially the same as the plan view of the substrate 100 described with reference to FIG. 5A. In other words, the substrate 100 may include a region corresponding to the island portion 11, a region corresponding to the bridge portion 12, and an opening 100OP1 having the same shape as a shape of the first opening CS1.

Similarly, the encapsulation layer 300 corresponding to the island portion 11 and the encapsulation layer 300 corresponding to the bridge portion 12 may be connected to each other. As an example, the plan views illustrated in FIGS. 4A to 4C may be substantially the same as the plan view of the encapsulation layer 300. In other words, the encapsulation layer 300 may include a region corresponding to the island portion 11, a region corresponding to the bridge portion 12, and the opening 300OP1 having the same shape as a shape of the first opening CS1.

A circuit-light-emitting element layer 200 between the substrate 100 and the encapsulation layer 300 may include the buffer layer 111, the pixel driving circuit PC, the wiring WL, the insulating layer IL, and the light-emitting element LED. Similar to the substrate 100, the plan views illustrated in FIGS. 4A to 4C may be substantially the same as the plan view of the circuit-light-emitting element layer 200. In other words, the circuit-light-emitting element layer 200 may include an opening 200OP1 having the same shape as a shape of the first opening CS1.

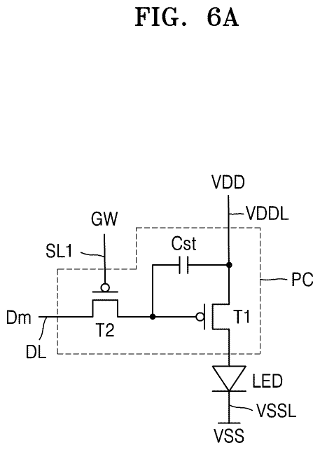

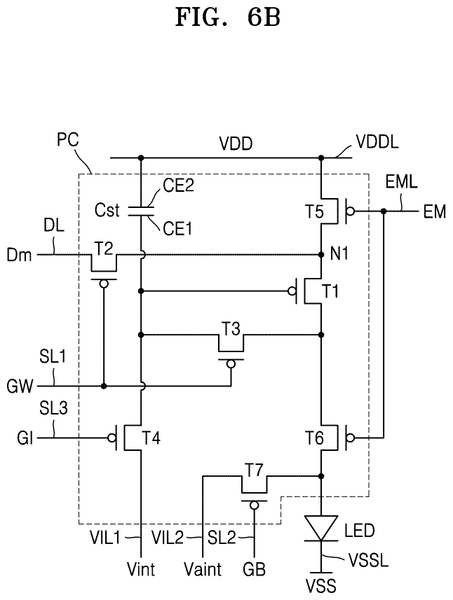

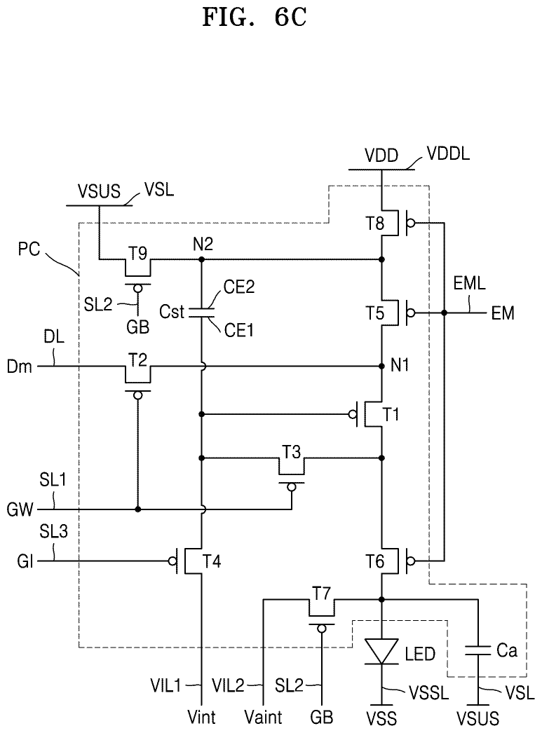

FIGS. 6A to 6C are schematic equivalent circuit diagrams of the light-emitting element LED and the pixel driving circuit PC according to an embodiment of the present invention.

Referring to FIG. 6A, the light-emitting element LED corresponding to a sub-pixel may be electrically connected to the pixel driving circuit PC, and the pixel driving circuit PC may include a first transistor T1, a second transistor T2, and a storage capacitor Cst. The pixel driving circuit PC may be electrically connected to a signal line and a voltage line. The signal line may include a gate line such as, for example, a first scan line SL1, and a data line DL, and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may be configured to transfer a data signal Dm to the first transistor T1 according to a first scan signal GW input from the first scan line GL1, wherein the data signal Dm is input from the data line DL.

The storage capacitor Cst may be electrically connected to the second transistor T2 and the first voltage line VDDL and may store a voltage corresponding to a difference between a voltage transferred from the second transistor T2 and a first power voltage VDD supplied by the first voltage line VDDL.

The first transistor T1 is a driving transistor and may control a driving current flowing through the light-emitting element LED. The first transistor T1 may be connected to the first voltage line VDDL and the storage capacitor Cst. The first transistor T1 may control the driving current flowing from the first voltage line VDDL to the light-emitting element LED in response to a voltage value stored in the storage capacitor Cst. The light-emitting element LED may emit light having a preset brightness based on the driving current. A first electrode of the light-emitting element LED may be electrically connected to the first transistor T1, and a second electrode may be electrically connected to a second voltage line VSSL supplying a second power voltage VSS.

Although it is illustrated in FIG. 6A that the pixel driving circuit PC includes two transistors and one storage capacitor, the pixel driving circuit PC may include three or more transistors in another embodiment.

Referring to FIG. 6B, the pixel driving circuit PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit PC is electrically connected to signal lines and voltage lines. The signal lines may include a gate line such as, for example, the first scan line SL1, a second scan line SL2, a third scan line SL3, and an emission control line EML, and the data line DL. The voltage lines may include first and second initialization voltage lines VIL1 and VIL2, and the first voltage line VDDL.

The first voltage line VDDL may transfer the first power voltage VDD to the first transistor T1. The first initialization voltage line VIL1 may be configured to transfer a first initialization voltage Vint to the pixel driving circuit PC, wherein the first initialization voltage Vint initializes the first transistor T1. The second initialization voltage line VIL2 may be configured to transfer a second initialization voltage Vaint to the pixel driving circuit PC, wherein the second initialization voltage Vaint initializes a first electrode of the light-emitting element LED.

The first transistor T1 may be connected to the first voltage line VDDL through the fifth transistor T5 and electrically connected to the light-emitting element LED through the sixth transistor T6. The first transistor T1 serves as a driving transistor, and receives a data signal Dm and supplies the driving current to the light-emitting element LED according to a switching operation of the second transistor T2.

The second transistor T2 is a data-write transistor and is electrically connected to the first scan line SL1 and the data line DL. The second transistor T2 is electrically connected to the first voltage line VDDL through the fifth transistor T5. The second transistor T2 is turned on according to a first scan signal GW transferred through the first scan line SL1, and performs a switching operation of transferring a data signal Dm to a first node N1, the data signal Dm being transferred through the data line DL.

The third transistor T3 is electrically connected to the first scan line SL1 and electrically connected to the light-emitting element LED through the sixth transistor T6. The third transistor T3 may be turned on according to a first scan signal GW to diode-connect the first transistor T1, wherein the first scan signal GW is transferred through the first scan line SL1.

The fourth transistor T4 serves as a first initialization transistor and is electrically connected to the third scan line SL3 and the first initialization voltage line VIL1. The fourth transistor T4 may be turned on according to a third scan signal GI to initialize a voltage of the gate electrode of the first transistor T1 by transferring the first initialization voltage Vint to the gate electrode of the first transistor T1, wherein the first initialization voltage Vint is from the first initialization voltage line VIL1, and the third scan signal GI is transferred through the third scan line SL3. The third scan signal GI may correspond to a first scan signal of another pixel driving circuit disposed in a previous row of the corresponding pixel driving circuit PC.

The fifth transistor T5 may be an operation control transistor, and the sixth transistor T6 may be an emission control transistor. The fifth transistor T5 and the sixth transistor T6 may be electrically connected to the emission control line EML, simultaneously turned on according to an emission control signal EM transferred through the emission control line EML, and may form a current path such that the driving current flows in a direction from the first voltage line VDDL to the light-emitting element LED.

The seventh transistor T7 serves as a second initialization transistor and may be electrically connected to the second scan line SL2, the second initialization voltage line VIL2, and the sixth transistor T6. The seventh transistor T7 is turned on according to a second scan signal GB transferred through the second scan line SL2, and is configured to transfer the second initialization voltage Vaint from the second initialization voltage line VIL2 to the first electrode of the light-emitting element LED, thereby initializing the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 6C, the pixel driving circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit PC is electrically connected to signal lines and voltage lines. The signal lines may include a gate line such as, for example, the first scan line SL1, the second scan line SL2, the third scan line SL3, and the emission control line EML, and the data line DL. The voltage lines may include the first and second initialization voltage lines VIL1 and VIL2, a sustain voltage line VSL, and the first voltage line VDDL.

The first voltage line VDDL may transfer the first power voltage VDD to the first transistor T1. The first initialization voltage line VIL1 may be configured to transfer the first initialization voltage Vint to the pixel driving circuit PC, wherein the first initialization voltage Vint initializes the first transistor T1. The second initialization voltage line VIL2 may be configured to transfer the second initialization voltage Vaint to the pixel driving circuit PC, wherein the second initialization voltage Vaint initializes the first electrode of the light-emitting element LED. The sustain voltage line VSL may provide a sustain voltage VSUS to a second node N2, for example, the second electrode CE2 of the storage capacitor Cst during an initialization section and a data-write section.

The first transistor T1 may be electrically connected to the first voltage line VDDL through the fifth transistor T5 and the eighth transistor T8 and electrically connected to the light-emitting element LED through the sixth transistor T6. The first transistor T1 serves as a driving transistor, and may receive a data signal Dm and supply the driving current to the light-emitting element LED according to a switching operation of the second transistor T2.

The second transistor T2 is electrically connected to the first scan line SL1 and the data line DL and electrically connected to the first voltage line VDDL through the fifth transistor T5 and the eighth transistor T8. The second transistor T2 may be turned on according to a first scan signal GW transferred through the first scan line SL1 and may perform a switching operation of transferring a data signal Dm to the first node N1, wherein the data signal Dm is transferred through the data line DL.

The third transistor T3 is electrically connected to the first scan line SL1 and electrically connected to the light-emitting element LED through the sixth transistor T6. The third transistor T3 may be turned on according to a first scan signal GW to compensate for a threshold voltage of the first transistor T1 by diode-connecting the first transistor T1, wherein the first scan signal GW is transferred through the first scan line SL1.

The fourth transistor T4 is electrically connected to the third scan line SL3 and the first initialization voltage line VIL1, turned on according to a third scan signal GI transferred through the third scan line SL3, and initializes a voltage of the gate electrode of the first transistor T1 by transferring the first initialization voltage Vint from the first initialization voltage line VIL1 to the gate electrode of the first transistor T1. The third scan signal GI may correspond to a first scan signal of another pixel driving circuit disposed in a previous row of the corresponding pixel driving circuit PC.

The fifth transistor T5, the sixth transistor T6, and the eighth transistor T8 may be electrically connected to the emission control line EML, simultaneously turned on according to an emission control signal EM transferred through the emission control line EML, and may form a current path such that the driving current flows in a direction from the first voltage line VDDL to the light-emitting element LED.

The seventh transistor T7 serves as a second initialization transistor and may be electrically connected to the second scan line SL2, the second initialization voltage line VIL2, and the sixth transistor T6. The seventh transistor T7 is turned on according to a second scan signal GB transferred through the second scan line SL2, and is configured to transfer the second initialization voltage Vaint from the second initialization voltage line VIL2 to the first electrode of the light-emitting element LED, thereby initializing the first electrode of the light-emitting element LED.

The ninth transistor T9 may be electrically connected to the second scan line SL2, the second electrode CE2 of the storage capacitor Cst, and the sustain voltage line VSL. The ninth transistor T9 is turned on according to a second scan signal GB transferred through the second scan line SL2 and may transfer the sustain voltage VSUS to the second node N2, for example, the second electrode CE2 of the storage capacitor Cst during the initialization section and the data-write section.

Each of the eighth transistor T8 and the ninth transistor T9 may be electrically connected to the second node N2, for example, the second electrode CE2 of the storage capacitor Cst. In an embodiment, during the initialization section and the data-write section, the eighth transistor T8 may be turned off and the ninth transistor T9 may be turned on. During an emission section, the eighth transistor T8 may be turned on and the ninth transistor T9 may be turned off. Because the sustain voltage VSUS is transferred to the second node N2 during the initialization section and the data-write section, uniformity (e.g., long range uniformity (LRU)) in brightness of the display panel depending on a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may prevent a black brightness from rising when the sixth transistor T6 is turned off by storing and maintaining a voltage corresponding to a voltage difference between the first electrode of the light-emitting element LED and the sustain voltage line VSL while the seventh transistor T7 and the ninth transistor T9 are turned on.

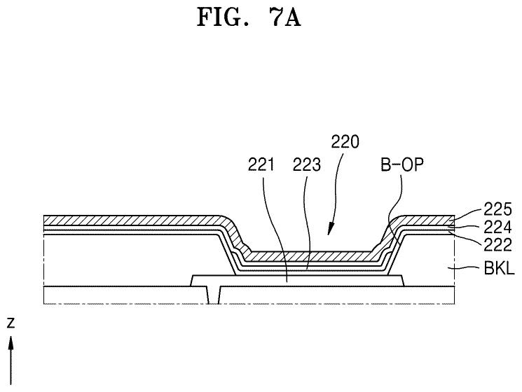

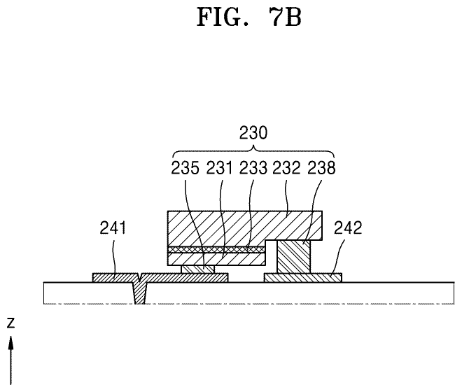

FIG. 7A is a schematic cross-sectional view of the light-emitting element of the display panel according to an embodiment of the present invention.

Referring to FIG. 7A, the light-emitting element according to an embodiment of the present invention may include an organic light-emitting diode 220 including an organic material. The organic light-emitting diode 220 may include a first electrode 221 disposed on an insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

The edge of the first electrode 221 may be covered by a bank layer BKL including an insulating material. The bank layer BKL may include an opening B-OP overlapping the central portion of the first electrode 221.

The first electrode 221 may include a conductive oxide such as, for example, indium tin oxide (ITO), indium zinc oxide (IZO), zinc oxide (ZnO), indium oxide (In₂O₃), indium gallium oxide (IGO), and/or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the first electrode 221 may further include a layer on/under the reflective layer, the layer including ITO, IZO, ZnO, AZO, or In₂O₃.

The emission layer 223 may include a polymer organic material or a low-molecular weight organic material emitting light having a preset color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. As an example, the second electrode 225 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the second electrode 225 may further include a layer on the (semi) transparent layer, the layer including ITO, IZO, ZnO, AZO, or In₂O₃.

FIG. 7B is a schematic cross-sectional view of the light-emitting element of the display panel according to an embodiment of the present invention.

Referring to FIG. 7B, the light-emitting element according to an embodiment of the present invention may be an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242 disposed on the same layer.

In an embodiment, the first semiconductor layer 231 may include a p-type semiconductor layer. The p-type semiconductor layer may be selected from among semiconductor materials having a composition formula of InₓAl_{y}Ga_{1-x-y}N (0≤x≤1, 0≤y≤1, 0≤x+y≤1), such as, for example, GaN, AlN, AlGaN, InGaN, InN, InAlGaN, AlInN, and the like, and may be doped with a p-type dopant such as, for example, Mg, Zn, Ca, Sr, or Ba.

The second semiconductor layer 232 may include, for example, an n-type semiconductor layer. The n-type semiconductor layer may be selected from among semiconductor materials having a composition formula of InₓAl_{y}Ga_{1-x-y}N (0≤x≤1, 0≤y≤1, 0≤x+y≤1), such as, for example, GaN, AlN, AlGaN, InGaN, InN, InAlGaN, AlInN, and the like, and may be doped with an n-type dopant such as, for example, Si, Ge, or Sn.

The intermediate layer 233 is a region in which electrons and holes recombine, and when electrons and holes recombine, they transition to a lower energy level and light having a corresponding wavelength may be created. The intermediate layer 233 may include, for example, a semiconductor material having a composition formula of InₓAl_{y}Ga_{1-x-y}N (0≤x≤1, 0≤y≤1, 0≤x+y≤1), and be formed in a single quantum-well structure or a multi quantum-well structure. In some aspects, the intermediate layer 233 may include a quantum-wire structure or a quantum-dot structure.

Although it is described in FIG. 7B that the first semiconductor layer 231 includes a p-type semiconductor layer and the second semiconductor layer 232 includes an n-type semiconductor layer, embodiments of the present disclosure are not limited thereto. In another embodiment, the first semiconductor layer 231 may include an n-type semiconductor layer, and the second semiconductor layer 232 may include a p-type semiconductor layer.

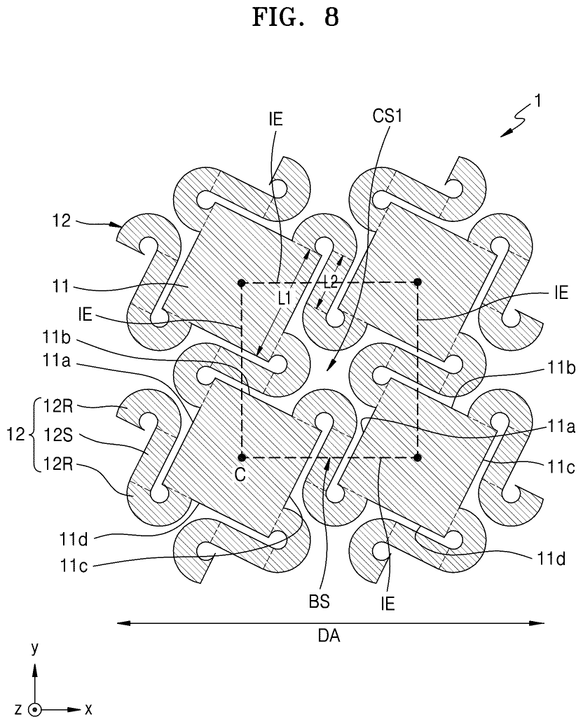

FIG. 8 is an excerpted plan view of the island portions 11 and the bridge portions 12 disposed in the display area DA of the display panel 1 according to an embodiment of the present invention.

Referring to FIG. 8, the island portions 11 may be apart from each other in the first direction (e.g., x direction or −x direction) and the second direction (e.g., y direction or −y direction). Sides of adjacent island portions 11 may be disposed side-by-side. A first side 11a of one island portion 11 may be parallel to a third side 11c of another island portion 11 adjacent in the first direction (e.g., −x direction), and a third side 11c of the one island portion 11 may be parallel to a first side 11a of another island portion 11 adjacent in the first direction (e.g., x direction). A second side 11b of one island portion 11 may be parallel to a fourth side 11d of another island portion 11 adjacent in the second direction (e.g., y direction), and a fourth side 11d of the one island portion 11 may be parallel to a second side 11b of another island portion 11 adjacent in the second direction (e.g., −y direction).

The bridge portion 12 may include two curved portions 12R respectively connected to two adjacent island portions 11, and a straight portion 12S between the two curved portions 12R. A length L1 of at least one side of the island portion 11 may be greater than a length L2 of the straight portion 12S of the bridge portion 12. In other words, the length L2 of the straight portion 12S of the bridge portion 12 may be less than the length L1 of at least one side of the island portion 11. As an example, a length L1 of at least one of the first to fourth sides 11a, 11b, 11c, and 11d of the island portion 11 may be greater than a length L2 of the straight portion 12S of the bridge portion 12. In an embodiment, the lengths of the first to fourth sides 11a, 11b, 11c, and 11d of the island portion 11 may be equal to each other.

The bridge portion 12 may be located to cross sides IE of the imaginary quadrilateral BS connecting the centers C of adjacent four island portions 11 around the first opening CS1. As an example, the straight portions 12S of the bridge portion 12 may respectively cross the sides IE of the imaginary quadrilateral BS. In an embodiment, an angle between one side of the straight portion 12S and the side IE of the imaginary quadrilateral BS may be greater than 0° and less than 90°, and an angle between a side opposite to the one side of the straight portion 12S and the side IE of the imaginary quadrilateral BS may be greater than 90° and less than 180°.

The bridge portion 12 may be located between two adjacent island portions 11 and located between facing sides of the two island portions 11. As an example, the straight portion 12S of the bridge portion 12 may be located between facing sides of the two island portions 11. The straight portion 12S of one bridge portion 12 may be located between the first side 11a of the one island portion 11 and the third side 11c of an adjacent island portion 11. The straight portion 12S of one bridge portion 12 may be located between the second side 11b of the one island portion 11 and the fourth side 11d of an adjacent island portion 11, the straight portion 12S of one bridge portion 12 may be located between the third side 11c of the one island portion 11 and the first side 11a of an adjacent island portion 11, and the straight portion 12S of one bridge portion 12 may be located between the fourth side 11d of the one island portion 11 and the second side 11b of an adjacent island portion 11.

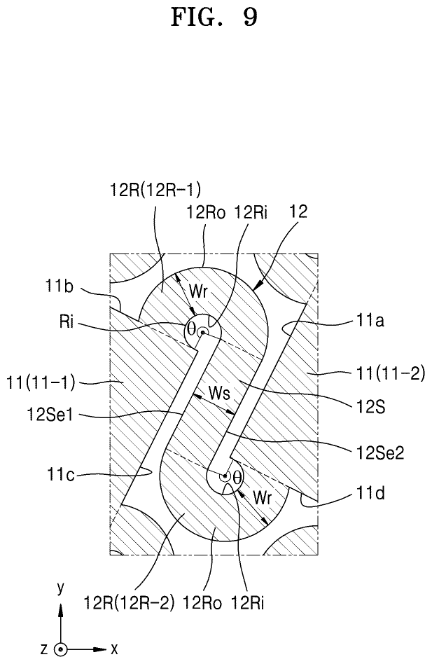

FIG. 9 is a plan view of two adjacent island portions 11 and a bridge portion 12 therebetween of the display panel 1 according to an embodiment of the present invention.

Referring to FIG. 9, two adjacent island portions 11 are connected by the bridge portion 12, and the bridge portion 12 may include two curved portions 12R and the straight portion 12S. Hereinafter, for convenience of description, two adjacent island portions 11 are referred to as an island portion 11-1 and a second island portion 11-2, and two curved portions 12R of each bridge portion 12 are respectively referred to as a first curved portion 12R-1 and a second curved portion 12R-2.

The first curved portion 12R-1 may be connected to the island portion 11-1, the second curved portion 12R-2 may be connected to the second island portion 11-2, and the straight portion 12S may be located between the first curved portion 12R-1 and the second curved portion 12R-2.

As an example, the first curved portion 12R-1 is directly connected to one end of the straight portion 12S and a side (e.g., the second side 11b) of the island portion 11-1, and may extend counterclockwise from one end of the straight portion 12S toward the side (e.g., the second side 11b) of the island portion 11-1. The second curved portion 12R-2 is directly connected to the other end of the straight portion 12S and a side (e.g., the fourth side 11d) of the second island portion 11-2, and may extend counterclockwise from the other end of the straight portion 12S toward the side (e.g., the fourth side 11d) of the second island portion 11-2. The first curved portion 12R-1 and the second curved portion 12R-2 have a structure continuously extending without an inflection point and may have a shape of a type of a circular arc.

The straight portion 12S may be located between a side (e.g., the third side 11c) of the island portion 11-1 and a side (e.g., the first side 11a) of the second island portion 11-2 facing each other. Each of the first curved portion 12R-1 and the second curved portion 12R-2 may be connected to a side bent and/or crossing with respect to each of the first and second island portions 11-1 and 11-2 disposed on two opposite sides of the straight portion 12S. As an example, the first curved portion 12R-1 may be connected to the second side 11b crossing the third side 11c of the island portion 11-1, and the second curved portion 12R-2 may be connected to the fourth side 11d crossing the first side 11a of the second island portion 11-2. Referring to FIGS. 8 and 9, the first curved portion 12R-1 is connected to the second side 11b of the island portion 11-1 and may be disposed adjacent to a corner between the third side 11c and the second side 11b. The second curved portion 12R-2 is connected to the fourth side 11d of the second island portion 11-2 and may be disposed adjacent to a corner between the fourth side 11d and the first side 11a.

The first curved portion 12R-1 includes a round inner edge 12Ri and a round outer edge 12Ro, and an interval between the inner edge 12Ri and the outer edge 12Ro may correspond to a width Wr of the first curved portion 12R-1. In an embodiment, the width Wr of the first curved portion 12R-1 may be substantially constant.

The first curved portion 12R-1 may have an approximate shape of a circular arc with a central angle θ of about 180° or more. In some embodiments, the central angle θ may be equal to or greater than about 180° and less than 360° (180°≤θ<360°). In some embodiments, the central angle θ of the first curved portion 12R-1 may be a reflex angle. For example, the central angle θ of the first curved portion 12R-1 may be greater than 180° and less than 360°(180°<θ<360°).

The second curved portion 12R-2 may have substantially the same structure as the first curved portion 12R-1. In some embodiments, the second curved portion 12R-2 may have an approximate shape of a circular arc with a central angle θ equal to or greater than about 180° and less than 360°(180°≤θ<360°). In some embodiments, the central angle θ of the second curved portion 12R-2 may be a reflex angle. For example, the central angle θ of the second curved portion 12R-2 may be greater than 180° and less than 360°(180°<θ<360°). The second curved portion 12R-2 includes a round inner edge 12Ri and a round outer edge 12Ro, and an interval between the inner edge 12Ri and the outer edge 12Ro may correspond to a width Wr of the second curved portion 12R-2.

The straight portion 12S includes a first side 12Se1 and a second side 12Se2 located opposite to each other. The first side 12Se1 of the straight portion 12S is connected to the inner edge 12Ri of the first curved portion 12R-1 and the outer edge 12Ro of the second curved portion 12R-2, and may face one side (e.g., the third side 11c) of the island portion 11-1. The second side 12Se2 of the straight portion 12S is connected to the outer edge 12Ro of the first curved portion 12R-1 and the inner edge 12Ri of the second curved portion 12R-2, and may face one side (e.g., the first side 11a) of the second island portion 11-2.

The straight portion 12S has a width Ws corresponding to an interval between the first side 12Se1 and the second side 12Se2. The width Ws of the straight portion 12S may be substantially constant. The width Ws of the straight portion 12S may be substantially the same as a width Wr of the first curved portion 12R-1 and a width Wr of the second curved portion 12R-2.

In an embodiment, the first side 12Se1 and the second side 12Se2 of the straight portion 12S may be substantially parallel to sides of the first and second island portions 11-1 and 11-2 disposed on two opposite sides of the straight portion 12S. As an example, the first side 12Se1 of the straight portion 12S may be parallel to the third side 11 c, which is a side of the island portion 11-1, and the second side 12Se2 may be parallel to the first side 11a of the island portion 11-1.

Although it is illustrated in FIG. 9 that the first side 12Se1 and the second side 12Se2 of the straight portion 12S are respectively parallel to island portions, for example, sides of the first and second island portions 11-1 and 11-2, embodiments of the present disclosure are not limited thereto. In another embodiment, the first side 12Se1 and the second side 12Se2 of the straight portion 12S may not be respectively parallel to island portions, for example, sides of the first and second island portions 11-1 and 11-2.

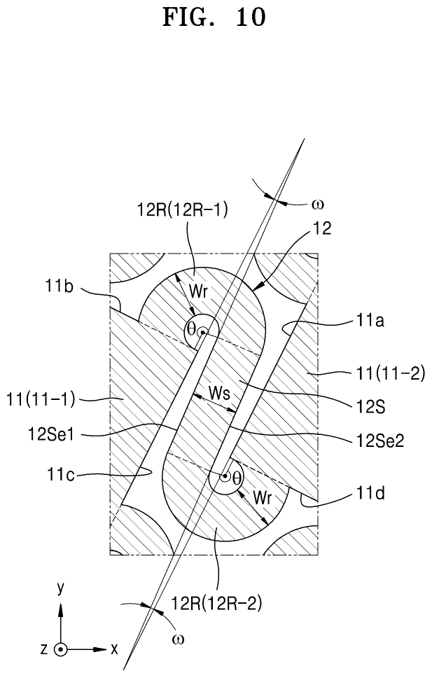

FIG. 10 is a plan view of two adjacent island portions 11 and a bridge portion 12 therebetween of the display panel 1 according to an embodiment of the present invention. The first and second island portions 11-1 and 11-2 illustrated in FIG. 10 are substantially the same as those described herein with reference to FIG. 9 and are different in the structure of the straight portion 12S of the bridge portion 12. The same description is replaced by the description made above with reference to FIG. 9, and differences are mainly described herein.

The straight portion 12S of the bridge portion 12 is located between the third side 11c of the island portion 11-1 and the first side 11a of the second island portion 11-2, and may include the first side 12Se1 and the second side 12Se2.

The first side 12Se1 of the straight portion 12S faces the third side 11 c of the island portion 11-1 and may extend in a direction oblique with respect to the third side 11c of the island portion 11-1. As an example, an angle ω between the third side 11c of the island portion 11-1 and the first side 12Se1 of the straight portion 12S may be an acute angle. In an embodiment, an angle ω between the third side 11c of the island portion 11-1 and the first side 12Se1 of the straight portion 12S may be greater than 0° and less than 30°.

The second side 12Se2 of the straight portion 12S faces the first side 11a of the second island portion 11-2 and may extend in a direction oblique with respect to the first side 11a of the second island portion 11-2. As an example, an angle ω between the first side 11a of the second island portion 11-2 and the second side 12Se2 of the straight portion 12S may be an acute angle. In an embodiment, an angle ω between the first side 11a of the second island portion 11-2 and the second side 12Se2 of the straight portion 12S may be greater than 0° and less than 30°.

The width Ws of the straight portion 12S may be substantially the same as the width Wr of each of the first curved portion 12R-1 and the first curved portion 12R-2. The width Ws of the straight portion 12S may be constant and the width Wr of each of the first curved portion 12R-1 and the first curved portion 12R-2 may be constant.

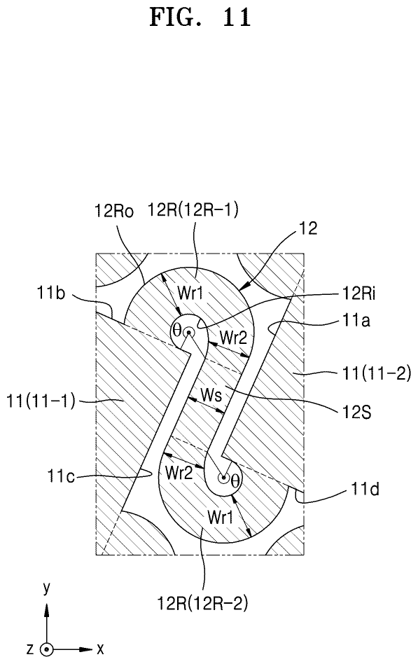

FIG. 11 is a plan view of two adjacent island portions 11 and a bridge portion 12 therebetween of the display panel 1 according to an embodiment of the present invention. The first and second island portions 11-1 and 11-2 and the bridge portion 12 illustrated in FIG. 11 are substantially the same as those described herein with reference to FIG. 9, and the widths of the first and second curved portions 12R-1 and 12R-2 and the width of the straight portion 12S of FIG. 11 are different from the characteristics described herein with reference to FIG. 9. The same description is replaced by the description made above with reference to FIG. 9, and differences are mainly described herein.

The width of each of the first and second curved portions 12R-1 and 12R-2 of the bridge portion 12 may be different from the width of the straight portion 12S. The width of a portion of each of the first and second curved portions 12R-1 and 12R-2 of the bridge portion 12 may be greater than the width Ws of the straight portion 12S. In an embodiment, a width (e.g., Wr1) of a portion of each of the first and second curved portions 12R-1 and 12R-2 of the bridge portion 12, for example, a portion that is relatively closer to the island portion 11-1 and the second island portion 11-2 may be greater than the width Ws of the straight portion 12S.

The width of each of the first and second curved portions 12R-1 and 12R-2 of the bridge portion 12 may not be varied. As an example, a first width Wr1 of a portion of the first curved portion 12R-1 that is relatively closer to the island portion 11-1 may be different from a second width Wr2 of a portion of the first curved portion 12R-1 that is relatively closer to the straight portion 12S. As an example, the first width Wr1 may be greater than the second width Wr2. A first width Wr1 of a portion of the second curved portion 12R-2 that is relatively closer to the second island portion 11-2 may be different from a second width Wr2 of a portion of the first curved portion 12R-1 that is relatively closer to the straight portion 12S. As an example, the first width Wr1 may be greater than the second width Wr2. In an embodiment, the second width Wr2 may be greater than the width Ws of the straight portion 12S.

While the display panel performs a stretching operation, the inner edge 12Ri of each of the first curved portion 12R-1 and the second curved portion 12R-2 and the surroundings of the inner edge 12Ri are portions where stress is relatively concentrated compared to the outer edge 12Ro and the surroundings of the outer edge 12Ro. In an embodiment, as described herein with reference to FIG. 5A, the wiring WL (see FIG. 5A) for configuring the display panel may be disposed on the bridge portion 12. In this case, as the wiring WL (see FIG. 5A) is close to the inner edge 12Ri, stress exerted to the wiring WL (see FIG. 5A) may also increase. In contrast, as in an embodiment of the present invention, in the case where the width of each of the first curved portion 12R-1 and the second curved portion 12R-2, for example, the first width Wr1 and/or the second width Wr2 are greater than the width Ws of the straight portion 12S, because the wiring WL (see FIG. 5A) may be disposed apart from the inner edge 12Ri by a preset interval, the wiring WL (see FIG. 5A) may be protected from the stress.

In an embodiment, the first and second sides 12Se1 and 12Se2 of the straight portion 12S illustrated in FIG. 11 may be respectively parallel to the sides of each of the first and second island portions 11-1 and 11-2 located on two opposite sides of the straight portion 12S. As an example, the first side 12Se1 of the straight portion 12S may be parallel to the third side 11c of the island portion 11-1, and the second side 12Se2 of the straight portion 12S may be parallel to the first side 11a of the island portion 11-1. In another embodiment, as illustrated in FIG. 10, the first side 12Se1 of the straight portion 12S may be oblique with respect to the third side 11c of the island portion 11-1, and the second side 12Se2 of the straight portion 12S may be oblique with respect to the first side 11a of the island portion 11-1.

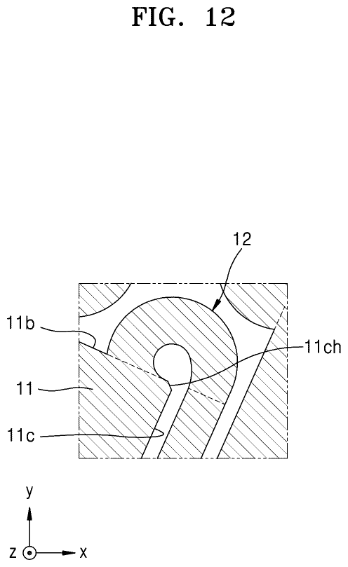

FIG. 12 illustrates a structure of a corner of an island portion and a bridge therearound of the display panel 1 according to an embodiment of the present invention.

Referring to FIG. 12, a corner between a side and a side of each island portion 11 may include a chamfered portion 11ch. In the embodiments described with reference to FIGS. 9 to 11, a corner between a side and a side of each island portion 11 may include a chamfered portion 11ch. In the case where a corner of each island portion 11 includes the chamfered portion, a process margin may be secured during an etching process for forming the first opening CS1. In an embodiment, it is illustrated in FIG. 12 that a corner between the second side 11b and the third side 11c of the island portion 11 includes the chamfered portion 11ch, embodiments of the present disclosure are not limited thereto. All corners (e.g., four corners of the island portion 11 illustrated in FIG. 8) of the island portion may include the chamfered portion 11ch.

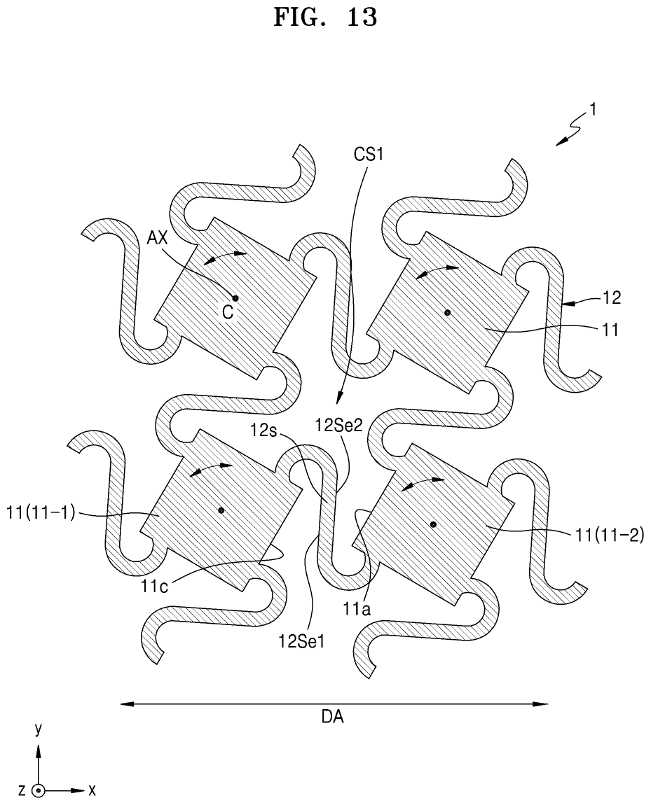

A structure according to the embodiment described with reference to FIGS. 4A to 4C and FIGS. 8 to 11 illustrates a state before the display panel (e.g., an unstretched state) is stretched. The display panel may be stretched as described herein with reference to FIG. 13.

FIG. 13 is a plan view of the display panel 1 stretched according to an embodiment of the present invention.

Referring to FIG. 13, when the display panel 1 is stretched, a gap between the island portions 11 disposed in the display area DA may increase, and each island portion 11 may rotate clockwise or counterclockwise around an imaginary axis AX passing through a center C. The imaginary axis AX is an axis perpendicular to the upper surface of the island portion 11, and FIG. 13 illustrates the axis AX extends in a z direction.

When the display panel 1 is stretched, the bridge portion 12 between two adjacent island portions 11 and a gap between two adjacent island portions 11 may increase. In an example in which the display panel 1 is stretched, the straight portion 12S of the bridge portion 12 between the island portion 11-1 and the second island portion 11-2 may move away from the third side 11c of the island section 11-1, and move away from the first side 11a of the second island portion 11-2.

The display panel 1 according to the above embodiments may be used in various electronic apparatuses that may display images. The electronic apparatuses represent apparatuses having a function that may display preset images using electricity.

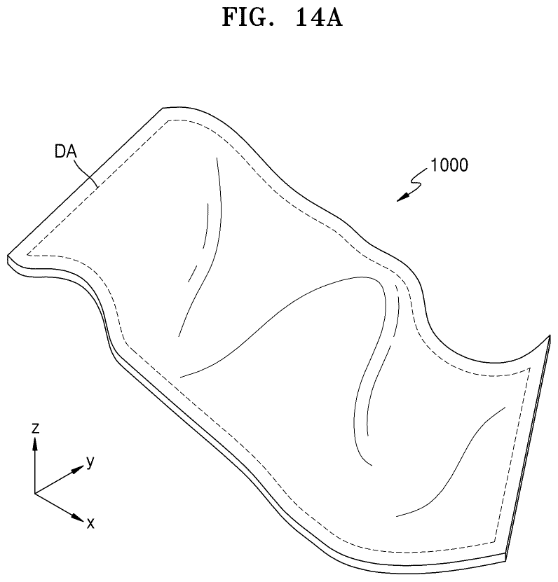

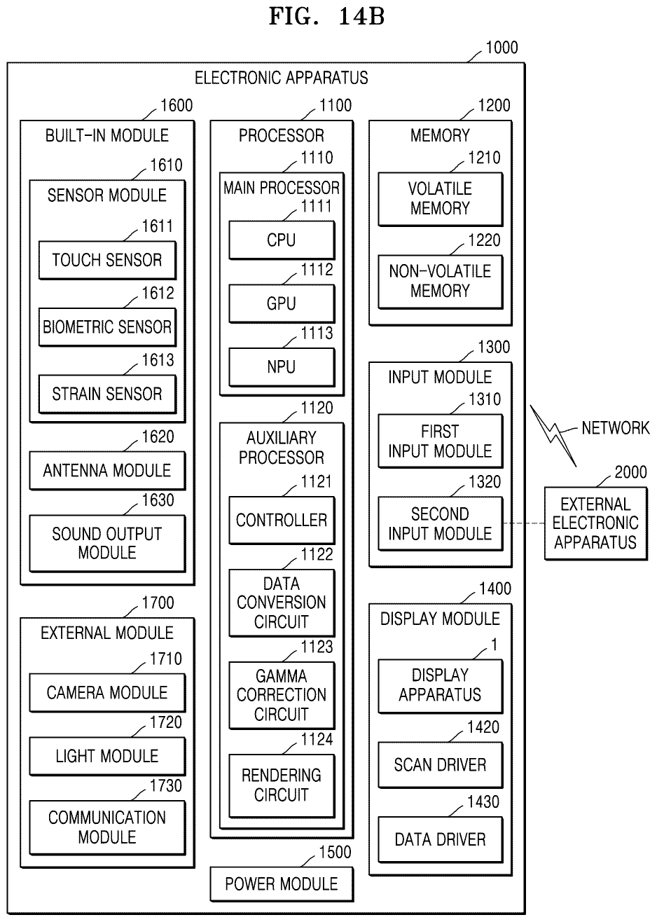

FIG. 14A is a schematic perspective view of an electronic apparatus 1000 including a display panel according to an embodiment of the present invention, and FIG. 14B is a schematic block diagram of the electronic apparatus 1000 including the display panel 1 according to an embodiment of the present invention.

Referring to FIG. 14A, the electronic apparatus 1000 is freely transformed three-dimensionally, and may provide a three-dimensional image surface through the display area DA. In an example in which the electronic apparatus 1000 is freely transformed three-dimensionally, it is distinguished from an operation of an electronic apparatus having a rollable display panel such as, for example, a case where a portion of a rolled-up display area is visible to a user and then another portion of the rolled-up display area is unfolded such that the entire display area is visible to the user (or a case where the entire unfolded display area is visible to the user and then the display area is rolled-up such that only a portion of the display area is visible to the user). The electronic apparatus 1000 according to embodiments of the present invention may represent transformation such as, for example, a case where the area of the entire display area DA increases or decreases again while the electronic apparatus 1000 is transformed in the x direction, y direction, and/or z direction.

Referring to FIG. 14B, the electronic apparatus 1000 may include a processor 1100, a memory 1200, an input module 1300, a display module 1400, a power module 1500, a built-in module 1600, and an external module 1700. According to an embodiment, in the electronic apparatus 1000, at least one of the elements may be omitted, or one or more other elements may be added. According to an embodiment, some (e.g., the built-in module 1600) of the elements may be integrated into another element (e.g., the display module 1400).

The processor 1100 may control at least one other element (e.g., a hardware or software element) of the electronic apparatus 1000 connected to the processor 1100 by executing software, and perform various data processes or operations. According to an embodiment, as at least some of data processes or operations, the processor 1100 may store commands or data received from another element (e.g., the input module 1300, a sensor module 1610, or a communication module 1730) in a volatile memory 1210, process the commands or data stored in the volatile memory 1210, and store result data in a non-volatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphic processing unit (GPU) 1112, a communication processor (CP), and an image signal processor (ISP). The main processor 1110 may further include a neural processing unit (NPU) 1113. The NPU is a processor specialized in processing artificial intelligence models, and the artificial intelligence models may be created through machine learning. The artificial intelligence models may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and a combination of two or more of the above, but is not limited to the examples described herein. The artificial intelligence models may additionally or alternatively include a software structure in addition to a hardware structure. At least two of the processing units and the processors may be implemented as one integrated construction (e.g., a single chip) or respectively implemented as independent constructions (e.g., a plurality of chips).

The auxiliary processor 1120 may include a controller 1121. The controller 1121 may include an interface conversion circuit and a timing control circuit. The controller 1121 receives image signals from the main processor 1110, converts a data format of image signals to match interface specifications of the display module 1400, and outputs image data. The controller 1121 may output various types of control signals supportive of driving the display module 1400.

The auxiliary processor 1120 may further include a data processing circuit such as, for example, a data conversion circuit 1122, a gamma correction circuit 1123, and a rendering circuit 1124. The data conversion circuit 1122 may receive image data from the controller 1121, correct image data such that images are displayed at desired brightness according to characteristics of the electronic apparatus 1000, a user's settings, or the like, or convert image data to reduce power consumption or compensate for an afterimage. The gamma correction circuit 1123 may convert image data, a gamma reference voltage, or the like such that images displayed by the electronic apparatus 1000 have desired gamma characteristics. The rendering circuit 1124 may receive image data from the controller 1121, and render the image data by taking into account the pixel configuration of the display panel 1 applied to the electronic apparatus 1000. At least one of the data conversion circuit 1122, the gamma correction circuit 1123, and the rendering circuit 1124 may be integrated into another element (e.g., the main processor 1110 or the controller 1121). In an embodiment, the auxiliary processor 1120 may be integrated into a data driver 1430.

The memory 1200 may store various data and input data or output data for commands related thereto, wherein the various data are used by at least one element (e.g., the processor 1100 or the sensor module 1610) of the electronic apparatus 1000. The memory 1200 may include at least one of the volatile memory 1210 and the non-volatile memory 1220.

The input module 1300 may receive commands or data from the outside (e.g., a user or an external electronic apparatus 2000) of the electronic apparatus 1000, wherein the commands or data are to be used by the element (e.g., the processor 1100, the sensor module 1610, or a sound output module 1630) of the electronic apparatus 1000.

The input module 1300 may include a first input module 1310 to which commands or data from a user are input, and a second input module 1320 to which commands or data from the external electronic apparatus 2000 are input.

The first input module 1310 may include a microphone, a mouse, a keyboard, or a pen (e.g., a passive pen or active pen). The first input module 1310 may include a mechanical input means such as, for example, buttons, a dome switch, a jog wheel, a jog switch, and the like, or a touch input means located on the lower surface or the lateral surface of the electronic apparatus 1000. The touch input means may include the touchscreen layer of the display panel 1.

The second input module 1320 may be connected to various types of external electronic apparatuses 2000 connected to the electronic apparatus 1000 via wires or wirelessly. In an embodiment, the second input module 1320 may include a high definition multimedia interface (HDMI), a universal serial bus (USB) interface, a secure digital (SD) card interface, or an audio interface. The second input module 1320 may include a connector that may physically connect the electronic apparatus 1000 to the external electronic apparatus 2000, wherein the connector includes an HDMI connector, a USB connector, an SD card connector, or an audio connector (e.g., a headphone connector). The electronic apparatus 1000 may perform appropriate control related to the connected external electronic apparatus 2000 in response to the external electronic apparatus 2000 being connected to the second input module 1320.

The display module 1400 provides a user with visual information. The display module 1400 may include the display panel 1, a scan driver 1420, and the data driver 1430.

The display panel 1 displays (outputs) information processed by the electronic apparatus 1000. The display panel 1 may display execution screen information of an application driven in the electronic apparatus 1000, or user interface (UI) and graphic user interface (GUI) information corresponding to the execution screen information.

The scan driver 1420 may be mounted on the display panel 1 as a driving chip. Alternatively, the scan driver 1420 may be directly formed on the display panel 1. As an example, the scan driver 1420 may include an amorphous silicon thin-film transistor (TFT) gate driver circuit (ASG), a low temperature polycrystalline silicon (LTPS) TFT gate driver circuit, or an oxide semiconductor TFT gate (OSG) driver circuit embedded in the display panel 1. The scan driver 1420 receives control signals from the controller 1121 and outputs scan signals to the display panel 1 in response to control signals.

The display panel 1 may further include an emission control driver. The emission control driver outputs an emission control signal to the display panel 1 in response to a control signal received from the controller 1121. The emission control driver may be formed separately from the scan driver 1420 or integrated in the scan driver 1420.

The data driver 1430 receives a control signal from the controller 1121, converts image data into a data voltage in the form of an analog voltage in response to a control signal, and outputs data voltages to the display panel 1.

The data driver 1430 may be integrated into some elements of the auxiliary processor 1120. As an example, the data driver 1430 may be provided in a timing controller embedded driver IC including the controller 1121.

The data driver 1430 may be mounted on the display panel 1 as a driving chip. Alternatively, the data driver 1430 may be directly formed on the display panel 1. In the case where the scan driver 1420 and the data driver 1430 are directly formed on the display panel 1, the display panel 1 may be actually the display module 1400.

The power module 1500 supplies power to the elements of the electronic apparatus 1000. The power module 1500 may include a battery charging a power voltage. In some aspects, the power module 1500 has a connection port, and the connection port may be included in the second input module 1320 to which an external charger that supplies power to charge the battery is connected. Alternatively, the power module 1500 may include a wireless power transmission/reception member to charge the battery wirelessly. The wireless power transmission/reception member may include a plurality of coil-shaped antenna radiators. The power module 1500 may include a power management integrated circuit (PMIC). The PMIC supplies power optimized for each of the elements of the electronic apparatus 1000.

The electronic apparatus 1000 may further include the built-in module 1600 and the external module 1700. The built-in module 1600 may include the sensor module 1610, an antenna module 1620, and the sound output module 1630. The external module 1700 may include a camera module 1710, a light module 1720, and/or the communication module 1730.

The sensor module 1610 may include touch electrodes of the touchscreen layer of the display panel 1, and the touch sensor driver. The sensor module 1610 may sense an input due to a user's body or an input due to a pen, and generate an electrical signal or a data value corresponding to the input. The sensor module 1610 may include at least one of a touch sensor 1611, a biometric sensor 1612, and a strain sensor 1613.

The touch sensor 1611 may generate a data value corresponding to coordinate information of an input due to a user's body (e.g., fingers and the like) or an input due to a pen. The touch sensor 1611 may generate, as data values, changes in electrostatic capacity, pressure, or electromagnetism due to an input.

The biometric sensor 1612 may generate data values that recognize a portion of the user's body (e.g., fingerprints, irises, face, and the like) or generate data values corresponding to body information (e.g., blood pressure, moisture, heart rate, body composition, and the like). The biometric sensor 1612 may use an optical method, an ultrasonic method, or a capacitive method.

The strain sensor 1613 may include layers, patterns or wirings in which a measurable physical quantity changes according to the stretching of the display panel 1. As an example, the strain sensor 1613 may include layers, patterns or wirings in which a pressure, a resistance, and/or a capacitance changes due to the stretching of the display panel 1. In another embodiment, the strain sensor 1613 may include optical layers or optical patterns in which a transmittance and/or reflectivity changes due to the stretching of the display panel 1.

The electronic apparatus 1000 may improve the quality of images implemented by the display panel 1 or control the display panel 1 based on physical quantity changes due to the stretching of the display panel 1 measured by the strain sensor 1613. Control operations of the display panel 1 may include operations such as, for example, displaying an operation image for protecting the display panel 1, blocking voltages for driving the display panel 1, or stopping a stretching operation of the display panel 1.

In an embodiment, at least one of the touch sensor 1611, the biometric sensor 1612, and the strain sensor 1613 may be built into the display panel 1. As an example, at least one of the touch sensor 1611, the biometric sensor 1612, and the strain sensor 1613 may be formed during a process that is successive to the process of forming the pixel driving circuit and/or the light-emitting element of the display panel 1. Accordingly, the display panel 1 may serve as one of the input modules 1300 that provide an input interface between the electronic apparatus 1000 and a user, and simultaneously, serve as the display module 1400 that provides an output interface between the electronic apparatus 1000 and a user.

In an embodiment, at least two of the touch sensor 1611, the biometric sensor 1612, and the strain sensor 1613 may be formed to be integrated in one sensing panel through the same process. In an embodiment, although the sensing panel may be disposed between the display panel 1 and a window cover disposed on a front surface of the display panel 1, embodiments of the present disclosure are not limited thereto.

The antenna module 1620 may include at least one antenna for transmitting signals or power to the outside or receiving signals or power from the outside. In an embodiment, the communication module 1730 may transmit signals to an external electronic apparatus or receive signals from an external electronic apparatus through an antenna suitable for a communication method. An antenna pattern of the antenna module 1620 may be integrated in one element (e.g., the display panel 1) of the display module 1400 or the input sensor 1612.

The sound output module 1630 is a device for outputting sound signals to the outside of the electronic apparatus 1000, and may output sound data received from the communication module 1730 or stored in the memory 1200 during call signal reception, a communication mode or recording mode, a voice recognition mode, a broadcasting reception mode, and the like. The sound output module 1630 may output sound signals related to a function (e.g., a call signal reception tone, a message reception tone, and the like) performed by the electronic apparatus 1000. The sound output module 1630 may include a receiver and a speaker. At least one of the receiver and the speaker may be a sound generator that is attached on the backside of the display panel 1 and vibrates the display panel 1 to output sounds. The sound generator may be a piezoelectric element or a piezoelectric actuator that contracts and expands according to electrical signals, or an exciter that generates magnetic force by using a voice coil to vibrate the display panel 1.

The camera module 1710 may capture still images and moving images. In an embodiment, the camera module 1710 may include at least one lens, an image sensor, or an image signal processor. The camera module 1710 may further include an infrared camera that may measure whether a user is present, a user's position, a user's gaze, and the like.

The light module 1720 may output signals for informing occurrence of an event using light of a light source, or provide light to obtain images. Here, examples of event occurrence include message reception, call signal reception, a missed call, an alarm, a calendar reminder, receiving an email, being notified of battery charge information, and the like. The light module 1720 may include a light-emitting diode or a xenon lamp. The light module 1720 may emit light of a single color or multiple colors to the front side or back side of the electronic apparatus 1000. The light module 1720 may operate in cooperation with the camera module 1710 or independently.

The communication module 1730 may establish a wired or wireless communication channel between the electronic apparatus 1000 and the external electronic apparatus 2000, and perform communication through the established communication channel. The communication module 1730 may include one or both of a wireless communication module, such as, for example, a cellular communication module, a short-range wireless communication module, or a global navigation satellite system (GNSS) communication module, and a wired communication module, such as, for example, a local area network (LAN) communication module, or a power line communication module. The communication module 1730 may transmit and receive wireless signals on the Internet using at least one of a wireless LAN) (WLAN), wireless-fidelity (Wi-Fi), Wi-Fi direct, and digital living network alliance (DLNA) technologies. In some aspects, the communication module 1730 may support short-range communication using at least one of Bluetooth™, RFID radio frequency identification (RFID), infrared data association (IrDA), ultra wideband (UWB), ZigBee, near field communication (NFC), Wi-Fi, Wi-Fi Direct, and wireless USB technologies. The above-described various types of communication modules 1730 may be implemented in one chip or respectively implemented as separate chips.

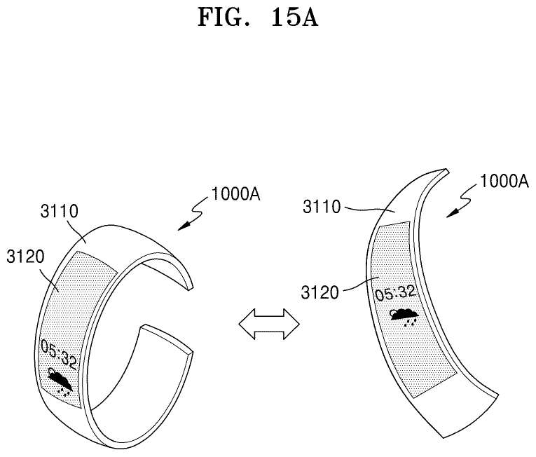

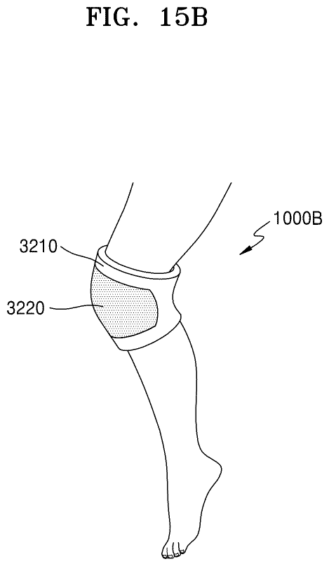

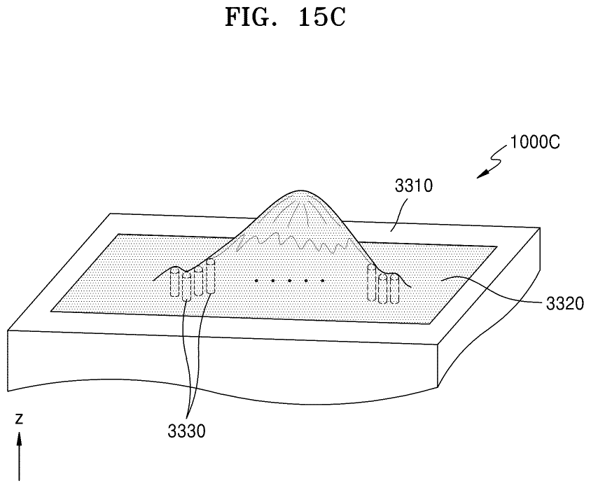

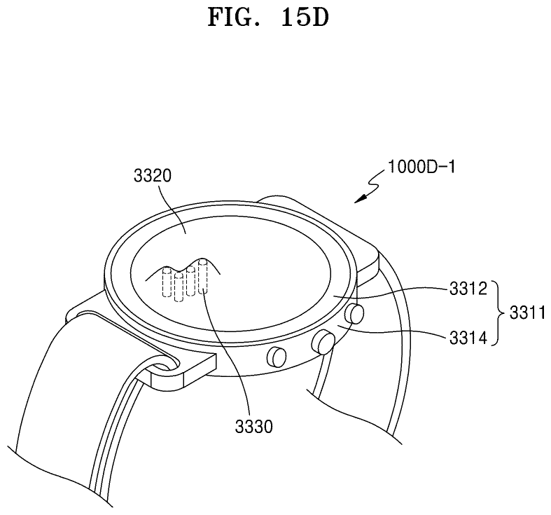

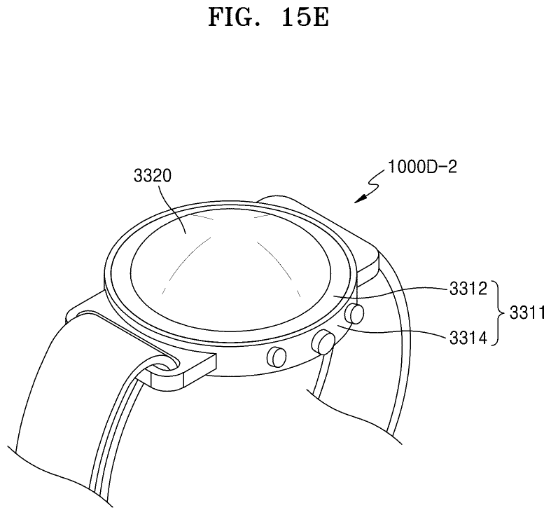

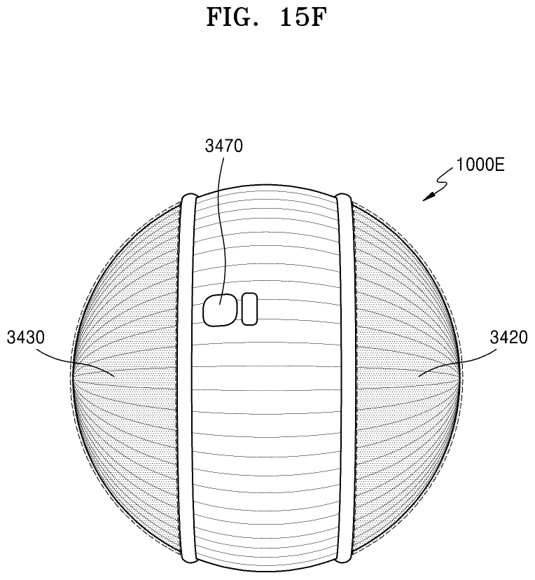

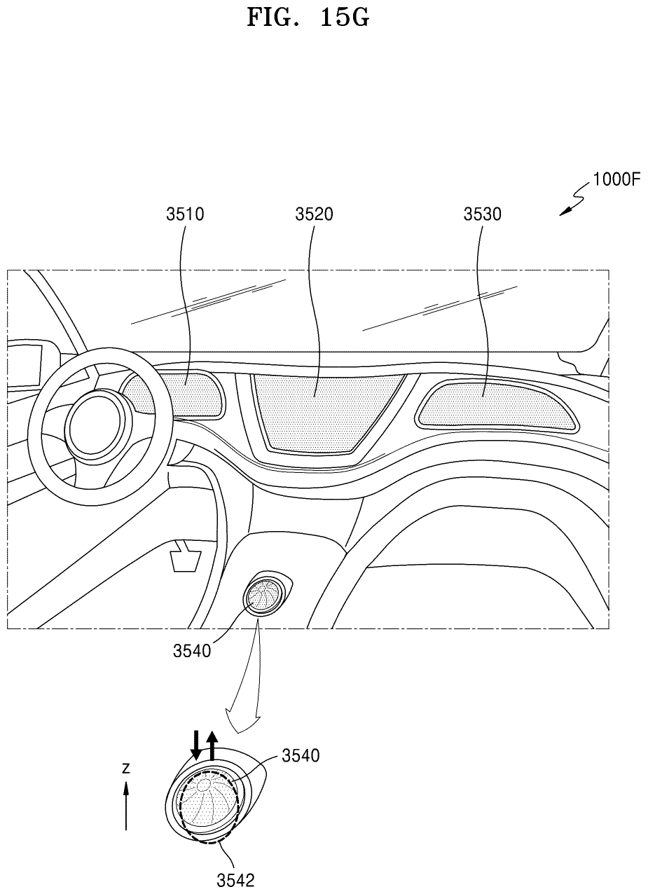

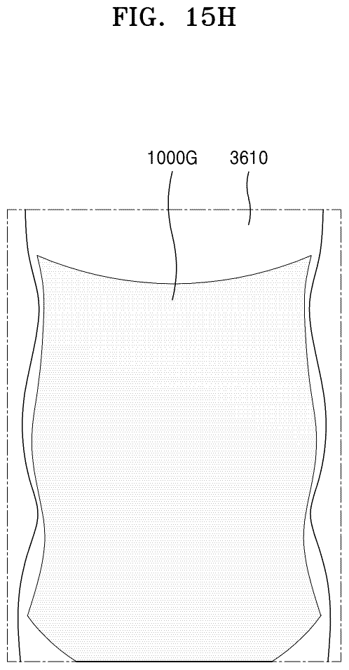

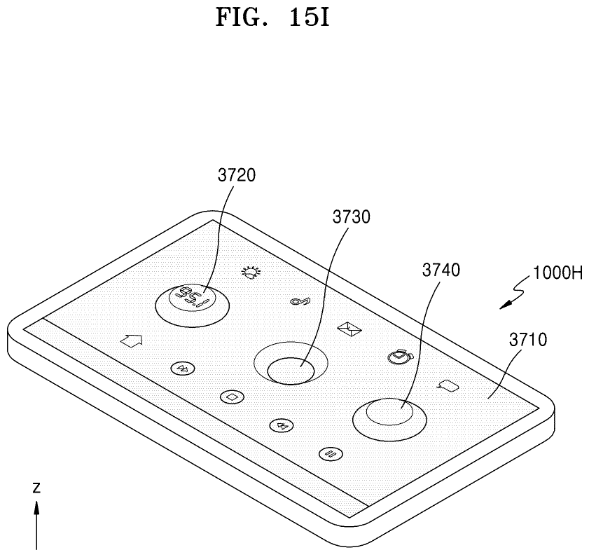

FIGS. 15A to 15I are schematic perspective views of an electronic apparatus including a display panel according to an embodiment of the present invention.

Referring to FIG. 15A, the display panel according to an embodiment of the present invention may be utilized in a wearable electronic apparatus 1000A that may be worn on a portion of a user's body. The wearable electronic apparatus 1000A may include a body portion 3110 and a display portion 3120 provided to the body portion 3110. The display panel according to embodiments of the present invention may be used as the display portion 3120 of the wearable electronic apparatus 1000A. As illustrated in FIG. 15A, the wearable electronic apparatus 1000A may be transformed. In an embodiment, the wearable electronic apparatus 3100 may be used as a smartwatch or a smartphone according to a user's selection.

FIG. 15B illustrates a medical electronic apparatus 1000B. In an embodiment, the medical electronic apparatus 1000B may include a body portion 3210 and a light-emitting portion 3220. The display panel according to embodiments of the present invention may be used as the display portion 3220 of the medical electronic apparatus 1000B. The light-emitting portion 3220 may emit light (e.g., infrared rays, visible rays, and the like) in a preset wavelength band to a patient's body. In an embodiment, the body portion 3210 may include a stretchable fiber material and have a structure that may be worn on the body of a user.

FIG. 15C illustrates an educational electronic apparatus 1000C. In an embodiment, the educational electronic apparatus may include a display portion 3320 provided inside a housing 3310. The display portion 3320 may be used as the display panel according to the embodiments of the present invention. An image such as, for example, a sea with crashing waves, a snow-covered mountain, or a volcano with flowing lava can be provided through the display portion 3320, and in this case, the display portion 3320 may be stretched in a height direction (e.g., z direction) to reflect the height of the wave, mountain, or volcano. In an embodiment, a portion of the display portion 3320 may be configured to sequentially change its height in a direction in which the lava flows, thereby illustrating the movement of the lava three dimensionally. The educational electronic apparatus 1000C may include a plurality of pins 3330 (or a stroke portion) disposed on the rear surface of the display portion 3320 such that the display portion 3320 is stretched in the height direction. The pins 3330 may be implemented to move in the third direction (e.g., z direction or −z direction) such that an image expressed on the display portion 3320 has a height three dimensionally. Although FIG. 15C describes the educational electronic apparatus 1000C, the purpose thereof is not limited thereto as far as the educational electronic apparatus provides preset image information.

FIGS. 15D and 15E show the display panel is used in wearable electronic apparatuses 1000D-1 and 1000D-2 such as, for example, a smartwatch.

In an embodiment, as illustrated in FIG. 15D, because the display panel corresponding to the display portion 3320 of the electronic apparatus 1000D-1 is stretchable three-dimensionally, the display panel may provide, to a user, various haptic information in addition to visual information through images. In an embodiment, the electronic apparatus 1000D-1 may provide haptic information, such as, for example, Braille display for the visually impaired or tactile stimulation linked to an image, by using a plurality of pins 3330 (or stroke portions) disposed below the display portion 3320. Because the display panel forming the display portion 3320 is stretchable three-dimensionally, the display panel may provide the haptic information to a user. The electronic apparatus 1000D-1 may include the body portion 3311, wherein the body portion 3311 includes a housing 3314 in which the display panel forming the display portion 3320 and the pins 3330 (or stroke portions) are accommodated, and a frame 3312 that may be coupled to the housing 3314 with the display panel therebetween. In an embodiment, the frame 3312 may be integrally formed with the housing 3314.

The electronic apparatus 1000D-2 of FIG. 15E may include the body portion 3311 and the display portion 3320 accommodated in the body portion 3311 and providing visual information as in FIG. 15D. In an embodiment, because the display panel corresponding to the display portion 3320 is stretchable three-dimensionally, the display panel may include the display portion 3320 of a dome shape. In an embodiment, the display panel may be assembled to the body frame of a dome shape during the process of manufacturing the electronic apparatus 1000D-2, and in this case, because the display panel is stretchable three-dimensionally, the display panel may be assembled while being stretched along the shape of the hemispherical body frame.

FIG. 15F illustrates an electronic apparatus 1000E according to an embodiment of the present invention includes a robot. The robot may recognize a movement or object using a camera module 3470 and display preset images to a user through display portions 3420 and 3430.

In an embodiment, because the display panels according to an embodiment of the present invention may be stretched in various directions as described herein, the display panels may be assembled to the body frame having a hemispherical shape, and thus, the robot may include the display portions 3420 and 3430 of a hemispherical shape.

FIG. 15G illustrates a vehicle display apparatus 1000F as an electronic apparatus according to an embodiment of the present invention. The vehicle display apparatus 1000F may include a cluster 3510, a center information display (CID) 3520, and/or a co-driver display 3530. Because the display panel according to an embodiment of the present invention may be stretched in various directions, the display panel may be used in the cluster 3510, the CID 3520, and/or the co-driver display 3530 without being restricted by the shape of an internal frame of the vehicle.

Although it is illustrated in FIG. 15G that the cluster 3510, the CID 3520, and/or the co-driver display 3530 are separated from each other, embodiments of the present disclosure are not limited thereto. In another embodiment, two or more selected from the cluster 3510, the CID 3520, and the co-driver display 3530 may be integrally connected.

In an embodiment, the vehicle display apparatus 1000F may include a button 3540 that may express preset images. Referring to an enlarged view of FIG. 15G, the button 3540 of a hemispherical shape may include an object 3542 and a display panel disposed on the object 3542, wherein the object 3542 provides the feel of a button while moving in the z direction or −z-direction. In an embodiment, in the case where the object 3542 has a three-dimensionally round surface, the display panel may also have a three-dimensionally round surface.

FIG. 15H illustrates an electronic apparatus according to an embodiment of the present invention is an electronic apparatus 1000G for advertising or display. In an embodiment, the electronic apparatus 1000G for advertising or display may be installed on a fixed structure 3610 such as, for example, a wall or pole. In the case where the structure 3610 includes an uneven surface as illustrated in FIG. 15H, the electronic apparatus 1000G for advertising or display may be also disposed along the uneven surface of the structure 3610. In an embodiment, the electronic apparatus 1000G for advertising or display may be installed on the structure 3610 using a heat shrink film.

FIG. 15I illustrates an electronic apparatus 1000H according to an embodiment of the present invention is a controller. The controller may include an image-type button. As an example, the controller may include first to third button regions 3720, 3730, and 3740 in which a portion of the display portion 3710 protrudes in the z direction or protrudes in the −z direction (or is recessed in the z direction). In an embodiment, the first and third button regions 3720 and 3740 may protrude in the z direction, and the second button region 3730 may protrude in the −z direction (or be recessed in the z direction).

While the present invention has been described with reference to an embodiment illustrated in the drawings, it will be understood by those of ordinary knowledge in the art that these are just examples and various changes and equivalent other embodiments may be made therefrom. Accordingly, the true technical scope of the present invention should be defined by the technical concept of the appended claims.

What is claimed is:

1. A display panel comprising:
a display area;
a non-display area around the display area:
island portions apart from each other in a first direction and a second direction crossing the first direction in the display area, wherein light-emitting elements are arranged in each of the island portions; and
bridge portions each connecting two adjacent island portions among the island portions,
wherein:
the island portions comprise a first island portion and a second island portion adjacent to each other in the first direction, each of the first island portion and the second island portion comprises at least one side crossing a first imaginary line passing through a center of the first island portion and a center of the second island portion, and the first imaginary line extends in the first direction,
a bridge portion which is among the bridge portions and connects the first island portion and the second island portion to each other comprises:
a first curved portion connected to the first island portion;
a second curved portion connected to the second island portion; and
a straight portion between the first curved portion and the second curved portion, and
the straight portion is located between a first side of the first island portion and a second side of the second island portion facing each other, the first curved portion is connected to a third side of the first island portion crossing the first side of the first island portion, and the second curved portion is connected to a fourth side of the second island portion crossing the second side of the second island portion.

2. The display panel of claim 1, wherein the first curved portion and the second curved portion have a point-symmetrical relationship with respect to a center of the straight portion.

3. The display panel of claim 2, wherein:
the first curved portion is connected to the third side of the first island portion and disposed adjacent to a corner between the first side and the third side of the first island portion, and
the second curved portion is connected to the fourth side of the second island portion and disposed adjacent to a corner between the second side and the fourth side of the second island portion.

4. The display panel of claim 3, wherein the corner between the first side and the third side of the first island portion comprises a chamfered portion.

5. The display panel of claim 1, wherein:
each of the first curved portion and the second curved portion has a shape of an arc having a central angle, and
the central angle is greater than 180° and less than 360°.

6. The display panel of claim 1, wherein a width of the first curved portion is substantially equal to a width of the straight portion.

7. The display panel of claim 1, wherein a width of a portion of the first curved portion is greater than a width of the straight portion.

8. The display panel of claim 1, wherein:
the straight portion comprises a side facing the first side of the first island portion, and
the side of the straight portion is substantially parallel to the first side of the first island portion.

9. The display panel of claim 1, wherein:
the straight portion comprises a side facing the first side of the first island portion, and
the side of the straight portion extends in a direction oblique with respect to the first side of the first island portion.

10. The display panel of claim 1, wherein a length of the straight portion is less than a length of the first side of the first island portion.

11. The display panel of claim 1, wherein:
the island portions further comprise a third island portion and a fourth island portion arranged in the second direction and disposed adjacent to the first island portion and the second island portion, and
the center of the first island portion, the center of the second island portion, a center of the third island portion, and a center of the fourth island portion are respectively disposed on vertexes of an imaginary quadrilateral.

12. The display panel of claim 11, wherein the straight portion of the bridge portion crosses one side of the imaginary quadrilateral.

13. The display panel of claim 11, wherein the imaginary quadrilateral comprises a square or a rhombus.

14. The display panel of claim 1, wherein:
the display panel is stretchable, and
when the display panel is stretched, the first island portion rotates clockwise or counterclockwise around an axis passing through the center of the first island portion.

15. The display panel of claim 1, wherein:
the first island portion comprises pixel driving circuits and light-emitting elements electrically connected to the pixel driving circuits, and
an arrangement direction of the pixel driving circuits and an arrangement direction of the light-emitting elements are different from each other.

16. A display panel comprising:
a display area;
a non-display area around the display area;
island portions apart from each other in a first direction and a second direction crossing the first direction in the display area; and
bridge portions each connecting two adjacent island portions among the island portions,
wherein:
the island portions comprise a first island portion and a second island portion adjacent to each other in the first direction, each of the first island portion and the second island portion comprises at least one side crossing a first imaginary line passing through a center of the first island portion and a center of the second island portion, and the first imaginary line extends in the first direction,
the first island portion comprises pixel driving circuits and light-emitting elements electrically connected to the pixel driving circuits, and
an arrangement direction of the pixel driving circuits and an arrangement direction of the light-emitting elements are different from each other.

17. The display panel of claim 16, wherein:
a bridge portion which is among the bridge portions and connects the first island portion and the second island portion to each other comprises:
a first curved portion connected to the first island portion;
a second curved portion connected to the second island portion; and
a straight portion between the first curved portion and the second curved portion, and
the straight portion is located between a first side of the first island portion and a second side of the second island portion facing each other, the first curved portion is connected to a third side of the first island portion crossing the first side of the first island portion, and the second curved portion is connected to a fourth side of the second island portion crossing the second side of the second island portion.

18. The display panel of claim 16, wherein:
the display panel is stretchable, and
when the display panel is stretched, the first island portion rotates clockwise or counterclockwise around an axis passing through the center of the first island portion.

19. An electronic apparatus comprising:
a display panel providing images; and
a housing in which the display panel is accommodated,
wherein the display panel comprises:
island portions apart from each other in a first direction and a second direction crossing the first direction, wherein light-emitting elements are arranged in each of the island portions; and
bridge portions each connecting two adjacent island portions among the island portions,
wherein:
the island portions comprise a first island portion and a second island portion adjacent to each other in the first direction, each of the first island portion and the second island portion comprises at least one side crossing a first imaginary line passing through a center of the first island portion and a center of the second island portion, and the first imaginary line extends in the first direction,
a bridge portion which is among the bridge portions connecting the first island portion and the second island portion to each other comprises:
a first curved portion connected to the first island portion;
a second curved portion connected to the second island portion; and
a straight portion between the first curved portion and the second curved portion, and
the straight portion is located between a first side of the first island portion and a second side of the second island portion facing each other, the first curved portion is connected to a third side of the first island portion crossing the first side of the first island portion, and the second curved portion is connected to a fourth side of the second island portion crossing the second side of the second island portion.

20. The electronic apparatus of claim 19, further comprising a strain sensor which measures a physical quantity according to stretching of the display panel.
